(19) United States
(12) Patent Application Publication
(10) Pub. No.: US 2025/0393416 A1
(43) Pub. Date: Dec. 25, 2025

(54) DISPLAY DEVICE AND ELECTRONIC DEVICE INCLUDING THE SAME

(71) Applicant: Samsung Display Co., Ltd., Yongin-Si (KR)

(72) Inventors: Tae Hyoung NO, Yongin-si (KR); Dae Yoon YOO, Yongin-si (KR); Kwang Chul JUNG, Yongin-si (KR); Yong Jun JO, Yongin-si (KR)

(21) Appl. No.: 18/959,631

(22) Filed: Nov. 26, 2024

(30) Foreign Application Priority Data
Jun. 21, 2024 (KR) 10-2024-0081183
Jul. 18, 2024 (KR) 10-2024-0095148

(51) Int. Cl. H10K 59/131; H10K 59/88

(52) U.S. Cl. CPC H10K 59/131; H10K 59/88

(57) ABSTRACT

A display device may include a substrate having a display area and a non-display area surrounding the display area, and a first fan-out line disposed in the non-display area. The first fan-out line may include a connection wiring line and an intermediate wiring line that are electrically connected to each other. The connection wiring line and the intermediate wiring line may be disposed on different layers. The connection wiring line may include a first sub-connection wiring line and a second sub-connection wiring line that are disposed spaced apart. The intermediate wiring line may include a first sub-intermediate wiring line and a second sub-intermediate wiring line that are disposed spaced apart.

### CROSS-REFERENCE TO RELATED APPLICATION

This application claims priority under 35 U.S.C. § 119(a) to Korean Patent Application number 10-2024-0081183 filed on Jun. 21, 2024 and Korean Patent Application number 10-2024-0095148 filed on Jul. 18, 2024 in the Korean Intellectual Property Office, the entire contents of which are incorporated herein by reference.

### BACKGROUND

### 2. Field

The present disclosure relates to a display device and an electronic device including the display device.

### 2. Description of the Related Art

The recent increase in interest in display has led to continuous research and development on display devices.

### SUMMARY

The present disclosure provides a display device capable of improving space utilization while reducing design constraints in a non-display area.

According to an embodiment of the present disclosure, a display device includes a substrate having a display area and a non-display area surrounding the display area, and a first fan-out line disposed in the non-display area. The first fan-out line may include a connection wiring line and an intermediate wiring line that are electrically connected to each other. The connection wiring line and the intermediate wiring line may be disposed on different layers. The connection wiring line may include a first sub-connection wiring line and a second sub-connection wiring line that are disposed spaced apart. The intermediate wiring line may include a first sub-intermediate wiring line and a second sub-intermediate wiring line that are disposed spaced apart. An end of the first sub-connection wiring line and an end of the first sub-intermediate wiring line may be electrically connected through a via. An end of the second sub-connection wiring line and an end of the second sub-intermediate wiring line may be electrically connected through a first contact hole. The via may include a plurality of vias, and the first contact hole may include a plurality of first contact holes. The plurality of vias and the plurality of first contact holes may be arranged along a direction inclined to an extension direction of the connection wiring line and the intermediate wiring line.

The plurality of vias and the plurality of first contact holes may be arranged alternately along the inclined direction.

The first sub-connection wiring line may be formed of a first conductive layer, the second sub-connection wiring line may be formed of a second conductive layer which disposed on the first conductive layer with a gate insulating layer interposed therebetween, the second sub-intermediate wiring line may be formed of a third conductive layer which is disposed on the second conductive layer with an interlayer insulating layer interposed therebetween, and the first sub-intermediate wiring line may be formed of a fourth conductive layer which disposed on the third conductive layer with a via layer interposed therebetween. The interlayer insulating layer may be disposed on the gate insulating layer, and the via layer may be disposed on the interlayer insulating layer.

One second sub-connection wiring line may be disposed between two adjacent first sub-connection wiring lines. One second sub-intermediate wiring line may be disposed between two adjacent first sub-intermediate wiring lines.

The end of the first sub-connection wiring line may include a first protrusion protruding in a first direction which intersects an extension direction of the first sub-connection wiring line. The end of the second sub-connection wiring line may include a second protrusion protruding in the first direction which intersects an extension direction of the second sub-connection wiring line. The end of the first sub-intermediate wiring line may include a third protrusion protruding in a second direction which intersects an extension direction of the first sub-intermediate wiring line. The end of the second sub-intermediate wiring line may include a fourth protrusion protruding in the second direction which intersects an extension direction of the second sub-intermediate wiring line. The first protrusion and the third protrusion may overlap each other, and the second protrusion and the fourth protrusion may overlap each other.

The display device may further include a contact electrode formed of the third conductive layer and located between the first protrusion and the third protrusion. The via layer may include the via extending to a part of the contact electrode, and the interlayer insulating layer may include the first contact hole extending to a part of the second protrusion and a second contact hole extending to a part of the first protrusion. The third protrusion may be electrically connected to the contact electrode through the via. The contact electrode may be electrically connected to the first protrusion through the second contact hole.

The via may be located in a first overlap area where the first protrusion and the third protrusion overlap in a plan view. The first contact hole may be located in a second overlap area where the second protrusion and the fourth protrusion overlap in a plan view. A longitudinal direction of the via may be parallel to a protrusion direction of the first and third protrusions.

The fourth protrusion may be electrically connected to the second protrusion through the first contact hole.

Some of the plurality of vias and some of the plurality of first contact holes may be arranged along a first virtual line extending in a first inclined direction which is inclined to the extension direction of the intermediate wiring line and the connection wiring line in a plan view. The rest of the plurality of vias and the rest of the plurality of first contact holes may be arranged along a second virtual line extending in a second inclined direction which is a different direction than the first inclined direction and faces the first inclined direction in a plan view. The first virtual line and the second virtual line may form a wedge shape.

Each of the first to fourth protrusions may include a first sub-protrusion arranged along the first inclined direction and a second sub-protrusion arranged along the second inclined direction. The first sub-protrusion and the second sub-protrusion may protrude in opposite directions to each other.

The display device may further include a dummy pattern located at a vertex of the wedge shape in the non-display area.

The dummy pattern may include a first dummy pattern and a second dummy pattern that are disposed spaced apart. The first dummy pattern may be formed of the fourth conductive layer, and the second dummy pattern may be formed of the third conductive layer. The first and second dummy patterns may be electrically isolated from the connection wiring line and the intermediate wiring line.

The display device may further include sub-pixels disposed in the display area, and a second fan-out line disposed in the non-display area, electrically connected to the sub-pixels, and electrically isolated from the first fan-out line. The second fan-out line may not overlap the connection wiring line but overlap the intermediate wiring line.

The second fan-out line may be disposed spaced apart from the plurality of vias and the plurality of first contact holes in a plan view.

The sub-pixels may include a pixel circuit layer disposed on the substrate and including at least one transistor, and a light-emitting element disposed on the pixel circuit layer and electrically connected to the transistor.

According to an embodiment of the present disclosure, a display device includes sub-pixels disposed in a display area of a substrate, a first fan-out line disposed in a non-display area of the substrate, and a second fan-out line disposed in the non-display area and electrically isolated from the first fan-out line. The first fan-out line may include a connection wiring line and an intermediate wiring line electrically connected to the connection wiring line. The connection wiring line may include a first sub-connection wiring line formed of a first conductive layer and a second sub-connection wiring line formed of a second conductive layer on the first conductive layer. The intermediate wiring line may include a second sub-intermediate wiring line formed of a third conductive layer on the second conductive layer and a first sub-intermediate wiring line formed of a fourth conductive layer on the third conductive layer. The first sub-connection wiring line and the first sub-intermediate wiring line may be electrically connected through a via. The second sub-connection wiring line and the second sub-intermediate wiring line may be electrically connected through a first contact hole. The via may include a plurality of vias, and the first contact hole may include a plurality of first contact holes. Some of the plurality of vias and some of the first contact holes may be arranged along a first virtual line extending in a first inclined direction which intersects an extension direction of the intermediate wiring line and the connection wiring line. The rest of the plurality of vias and the rest of the first contact holes may be arranged along a second virtual line extending in a second inclined direction which is a different direction than the first inclined direction and faces the first inclined direction. The first virtual line and the second virtual line may form a wedge shape.

An end of the first sub-connection wiring line and an end of the first sub-intermediate wiring line may overlap a corresponding via of the plurality of vias. An end of the second sub-connection wiring line and an end of the second sub-intermediate wiring line may overlap a corresponding first contact hole of the plurality of first contact holes. The end of the first sub-connection wiring line may protrude in a first direction which intersects an extension direction of the first sub-connection wiring line. The end of the second sub-connection wiring line may protrude in the first direction which intersects an extension direction of the second sub-connection wiring line. The end of the first sub-intermediate wiring line may protrude in a second direction which intersects an extension direction of the first sub-intermediate wiring line. The end of the second sub-intermediate wiring line may protrude in the second direction which intersects an extension direction of the second sub-intermediate wiring line.

The display device may further include a contact electrode located between the end of the first sub-connection wiring line and the end of the first sub-intermediate wiring line and formed of the third conductive layer. The contact electrode may be disposed on the same layer as the second sub-intermediate wiring line.

The display device may further include a dummy pattern located at a vertex of the wedge shape in the non-display area. The dummy pattern may be electrically isolated from the connection wiring line and the intermediate wiring line.

The first sub-connection wiring line and the second sub-connection wiring line may be disposed spaced apart from each other in a plan view. The first sub-intermediate wiring line and the second sub-intermediate wiring line may be disposed spaced apart from each other in a plan view.

According to an embodiment of the present disclosure, an electronic device includes a processor configured to provide input image data to a display device, and the display device configured to display an image based on the input image data. The display device may include a substrate having a display area and a non-display area surrounding the display area, and a first fan-out line disposed in the non-display area. The first fan-out line may include a connection wiring line and an intermediate wiring line that are electrically connected to each other. The connection wiring line and the intermediate wiring line may be disposed on different layers. The connection wiring line may include a first sub-connection wiring line and a second sub-connection wiring line that are disposed spaced apart. The intermediate wiring line may include a first sub-intermediate wiring line and a second sub-intermediate wiring line that are disposed spaced apart. An end of the first sub-connection wiring line and an end of the first sub-intermediate wiring line may be electrically connected through a via. An end of the second sub-connection wiring line and an end of the second sub-intermediate wiring line may be electrically connected through a first contact hole. The via may include a plurality of vias, and the first contact hole may include a plurality of first contact holes. The plurality of vias and the plurality of first contact holes may be arranged along a direction inclined to an extension direction of the connection wiring line and the intermediate wiring line.

According to an embodiment, each of the first fan-out lines disposed in a non-display area may be formed by including a connection wiring line and an intermediate wiring line which are disposed on different layers. The contact parts which electrically connect the connection wiring line and the intermediate wiring line may be arranged along a diagonal direction inclined to the extension direction of the connection wiring line and the intermediate wiring line. In this case, the spacing between adjacent contact parts can be further secured, thereby reducing the design constraints for maintaining the spacing between adjacent contact parts at a certain level or higher.

According to an embodiment, the contact parts may be arranged along a diagonal direction to form at least one or more wedge shapes in the non-display area. Due to this wedge shape, the spacing between the connection wiring line and the second fan-out line may be further secured. In this case, additional space for changing the shape of the second fan-out line in the non-display area, etc., can be secured.

The technical solutions and the effects of the present disclosure may not be limited to the above, and other technical solutions of the present disclosure will be clearly understandable to those having ordinary skill in the art from the disclosures provided below together with accompanying drawings.

### BRIEF DESCRIPTION OF THE DRAWINGS

FIG. 1 is a schematic perspective view illustrating a display device in accordance with an embodiment of the present disclosure.

FIG. 2 is a schematic plan view illustrating a display device in accordance with an embodiment.

FIG. 3 is a schematic block diagram showing an embodiment of one of the sub-pixels in FIG. 2.

FIG. 4 is a schematic plan view showing the pixel in FIG. 2.

FIG. 5 is a schematic cross-sectional view taken along a line I-I′ in FIG. 4.

FIG. 6 is a schematic plan view showing an enlarged view of the area EA1 in FIG. 2.

FIG. 7 is a schematic plan view showing an enlarged view of the area EA2 in FIG. 6.

FIG. 8 is a schematic plan view showing an enlarged view of the area EA4 in FIG. 7.

FIG. 9 is a schematic plan view showing an enlarged view of the area EA3 in FIG. 6.

FIG. 10 is a schematic plan view illustrating the first sub-connection wiring line and the second sub-connection wiring line in FIG. 9.

FIG. 11 is a schematic plan view illustrating the first sub-intermediate wiring line and the second sub-intermediate wiring line in FIG. 9.

FIG. 12 is a schematic cross-sectional view taken along a line II-II′ in FIG. 8.

FIG. 13 is a schematic cross-sectional view taken along a line III-III′ in FIG. 8.

FIG. 14 is a schematic cross-sectional view taken along lines IV-IV′ and V-V′ in FIG. 9.

FIG. 15 is a schematic plan view showing a part of a display device in accordance with an embodiment, corresponding to the EA1 portion in FIG. 2.

FIG. 16 is a schematic diagram schematically illustrating the first fan-out line in FIG. 15.

FIG. 17 is a schematic plan view showing a part of a display device in accordance with an embodiment, corresponding to the EA1 portion in FIG. 2.

FIG. 18 is a schematic diagram schematically illustrating the first fan-out line in FIG. 17.

FIG. 19 is a schematic block diagram illustrating an electronic device in accordance with an embodiment.

FIG. 20 is a schematic diagram illustrating an example where the electronic device of FIG. 19 is implemented as a smartphone.

FIG. 21 is a schematic diagram illustrating an example where the electronic device of FIG. 19 is implemented as a tablet computer.

### DETAILED DESCRIPTION OF THE EMBODIMENTS

Since the present disclosure may be modified in various ways and take multiple forms, particular embodiments will be illustrated in the drawings and described herein in detail. However, this is not intended to limit the present disclosure to any particular disclosed forms, and should be understood to include all modifications, equivalents, and alternatives that fall within the scope of the present disclosure.

Like reference numerals are used for like components in describing each drawing. In the accompanying drawings, the dimensions of the structures are exaggerated for the clarity of the present disclosure. Terms such as first and second may be used to describe various components, but the components should not be limited by such terms. The terms are used only for the purpose of distinguishing one component from another. For example, a first component may be named a second component, and similarly, a second component may also be named a first component, without departing from the scope of the present disclosure.

In the present disclosure, it should be understood that terms such as “comprise” or “have” are intended to specify the presence of features, numbers, steps, operations, components, parts, or combinations thereof described in the specification, and not to preclude the possibility of the presence or addition of one or more other features, numbers, steps, operations, components, parts, or combinations thereof. In addition, when a portion of a layer, film, area, plate, or the like is said to be “on” another portion, this includes not only the case where the portion is “directly on” said another portion, but also the case where there is another portion interposed therebetween. Further, in the present disclosure, when a portion of a layer, film, area, plate, or the like is said to be formed on another portion, the direction in which the portion is formed is not limited to the upward direction, but also includes forming in the lateral or downward direction. On the other hand, when a portion of a layer, film, area, plate, or the like is said to be “under” another portion, this includes not only the case where the portion is “directly under” said another portion, but also the case where there is another portion interposed therebetween.

Hereinafter, an embodiment of the present disclosure and other details necessary for those skilled in the art to readily understand the content of the present disclosure will be described in detail with reference to the accompanying drawings. In the description below, singular expressions include plural expressions unless the context explicitly indicates otherwise.

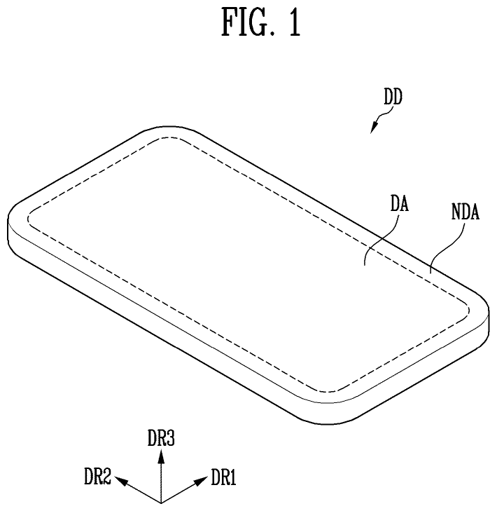

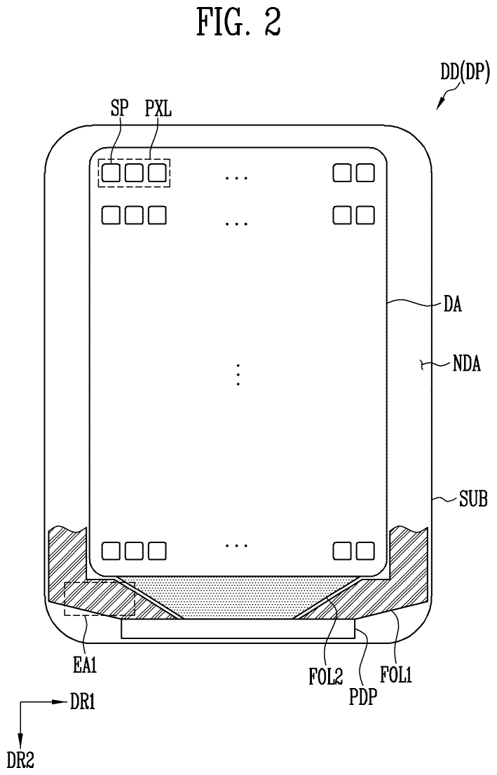

FIG. 1 is a schematic perspective view illustrating a display device DD in accordance with an embodiment, and FIG. 2 is a schematic plan view illustrating a display device DD in accordance with an embodiment. In FIG. 2, the structure of the display device DD, for example, a display panel DP provided in the display device DD, is simply illustrated with a focus on a display area DA in which an image is displayed, for convenience.

Referring to FIG. 1 and FIG. 2, the display device DD can display an image. The display device DD may refer to any electronic device that provides a display surface. For example, the display device DD may include a television, a laptop, a monitor, a billboard, Internet of Things, a mobile phone, a smartphone, a tablet PC (personal computer), an electronic watch, a smartwatch, a watch phone, a head-mounted display, a mobile communication terminal, an electronic notebook, an electronic book, a PMP (portable multimedia player), a navigation system, a game console, a digital camera, a camcorder, or the like that provides a display surface, but is not limited thereto.

The display device DD may be a flat display device, a flexible display device, a curved display device, a foldable display device, a bendable display device, or a rollable display device. In addition, the display device DD may be applied to a transparent display device, a head-mounted display device, a wearable display device, or the like.

The display device DD may include a display panel DP that provides a display surface. Examples of the display panel DP may include, but are not limited to, an inorganic light-emitting diode display panel, an organic light-emitting diode display panel, a quantum dot light-emitting display panel, a plasma display panel, a field emission display panel, or the like. The following describes an example of a display panel DP where an organic light-emitting diode display panel is applied. However, the present disclosure is not limited thereto and may be applied to other display panels as long as the same technical idea is applicable.

The shape of the display device DD may vary in a variety of ways. For example, the display device DD may have various shapes, such as a rectangle, a square, a rectangle with rounded corners (or vertices), other polygons, or a circle. The shape of the display area DA of the display device DD may also be similar to the overall shape of the display device DD. The display device DD and the display area DA having a rectangular shape with rounded corners are illustrated in FIG. 1 and FIG. 2.

The display device DD may include a display area DA and a non-display area NDA. The display area DA may be an area in which an image may be displayed, and the non-display area NDA may be an area in which an image is not displayed. The display area DA may be referred to as an active area, and the non-display area NDA may be referred to as an inactive area. The display area DA may be located in the center of the display device DD, but the present disclosure is not limited thereto.

The display area DA may be an area in which sub-pixels SP (or pixels) are provided. The sub-pixel SP may include at least one light-emitting element. For example, the light-emitting element may include a light-emitting layer (e.g., an organic light-emitting layer). The portion that emits light by the light-emitting element may be defined as a light-emitting area. The display device DD may display an image in the display area DA by driving the sub-pixels SP in response to image data.

The sub-pixels SP may be disposed in the display area DA on a substrate SUB. The sub-pixels SP may be arranged in a matrix form along a first direction DR1 and a second direction DR2 intersecting the first direction DR1, but the arrangement form of the sub-pixels SP is not limited thereto. For example, the sub-pixels SP may be arranged in a zigzag form along the first direction DR1 and the second direction DR2. For example, the sub-pixels SP may be disposed in a Pentile™ form. The first direction DR1 may be the row direction, and the second direction DR2 may be the column direction.

Two or more sub-pixels SP among a plurality of sub-pixels SP may constitute a single pixel PXL.

A pad part PDP and a fan-out part may be disposed in the non-display area NDA on the substrate SUB.

The pad part PDP may include a plurality of pads. The pads may be electrically connected to the sub-pixels SP through signal wiring lines. For example, the pads may be connected to the sub-pixels SP through data lines. The pad part PDP may interface the display panel DP to other components of the display device DD. In an embodiment, voltages and signals necessary for the operation of the components included in the display panel DP may be provided from a driver integrated circuit through the pad part PDP.

In an embodiment, a circuit board may be electrically connected to the pad part PDP by using a conductive adhesive member such as an anisotropic conductive film. In this case, the circuit board may be a flexible circuit board or a flexible film having a flexible material. The driver integrated circuit may be mounted on the circuit board and electrically connected to the pad part PDP.

A first side of the fan-out part may be electrically connected to the sub-pixels SP disposed in the display area DA, and a second side of the fan-out part, which is an opposite side to the first side of the fan-out part, may be electrically connected to the pad part PDP. The fan-out part may include fan-out lines that extend from the pad part PDP and are electrically connected to signal wiring lines disposed in the display area DA. For example, the fan-out part may include a first fan-out line FOL1 and a second fan-out line FOL2.

The first fan-out line FOL1 and the second fan-out line FOL2 may be electrically isolated. The first fan-out line FOL1 and the second fan-out line FOL2 may partially overlap.

The first fan-out line FOL1 may be electrically connected to a signal wiring line, for example, a data line, electrically connected to the sub-pixels SP. The first fan-out line FOL1 may extend from the pad part PDP to an area of the non-display area NDA surrounding the edges on both sides of the display area DA, but the present disclosure is not limited thereto. The first fan-out line FOL1 may electrically connect the data line disposed in the display area DA to the pad part PDP disposed in the non-display area NDA. The first fan-out line FOL1 may include a plurality of first fan-out lines.

The second fan-out line FOL2 may be electrically connected to a signal wiring line, for example, a gate line, electrically connected to the sub-pixels SP. The second fan-out line FOL2 may extend from the pad part PDP to an area of the non-display area NDA surrounding the lower edge of the display area DA, but the present disclosure is not limited thereto. The second fan-out line FOL2 may electrically connect the gate line disposed in the display area DA to the pad part PDP disposed in the non-display area NDA. The second fan-out line FOL2 may include a plurality of second fan-out lines.

In an embodiment, the display area DA may have a variety of shapes. The display area DA may have the shape of a closed loop including straight or curved sides. For example, the display area DA may have shapes such as a polygon, a circle, a semicircle, an ellipse, etc.

In an embodiment, the display panel DP may have a flat display surface. In another example, the display panel DP may have a display surface that is at least partially rounded. In an embodiment, the display panel DP may be bendable, foldable, or rollable. In these cases, the display panel DP and/or the substrate SUB may include materials having flexible properties.

In the present disclosure, the drawings illustrate the first direction DR1 to the third direction DR3. The directions indicated by the first direction DR1, the second direction DR2, and the third direction DR3 described herein are relative concepts and may be converted into other directions. For example, the first direction DR1 and the second direction DR2 may be orthogonal to each other, and the third direction DR3 may be a normal direction to a plane defined by the first direction DR1 and the second direction DR2, but the present disclosure is not limited thereto.

The thickness direction of the display device DD may be a direction parallel to the third direction DR3, which is the normal direction to the plane defined by the first direction DR1 and the second direction DR2.

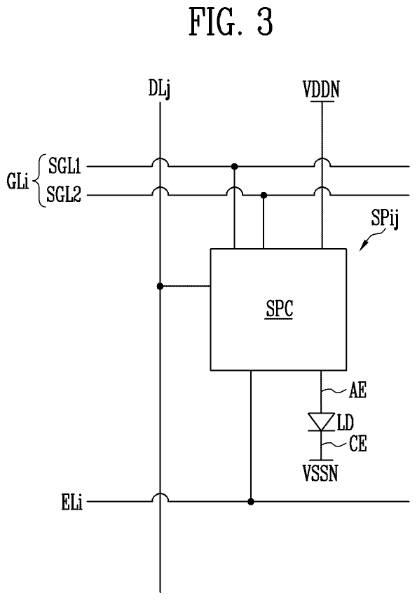

FIG. 3 is a schematic block diagram showing an embodiment of one of the sub-pixels in FIG. 2. In FIG. 3, a sub-pixel SPij arranged in the i-th row and j-th column ais illustrated as an example (where i and j are integers greater than or equal to 1).

Referring to FIG. 2 and FIG. 3, the sub-pixel SPij may include a sub-pixel circuit SPC and a light-emitting element LD.

The light-emitting element LD may be connected between a first power supply voltage node VDDN and a second power supply voltage node VSSN. The first power supply voltage node VDDN is a node that transmits a first power supply voltage, and the second power supply voltage node VSSN is a node that transmits a second power supply voltage. The first power supply voltage may have a relatively high voltage level, and the second power supply voltage may have a voltage level lower than the first power supply voltage.

The anode electrode AE of the light-emitting element LD may be connected to the first power supply voltage node VDDN through the sub-pixel circuit SPC, and the cathode electrode CE of the light-emitting element LD may be connected to the second power supply voltage node VSSN. For example, the anode electrode AE of the light-emitting element LD may be connected to the first power supply voltage node VDDN through one or more transistors included in the sub-pixel circuit SPC.

The sub-pixel circuit SPC may be electrically connected to signal lines. For example, the sub-pixel circuit SPC may be electrically connected to the i-th gate line GLi of the gate lines, the i-th light emission control line ELi of the light emission control lines, and the j-th data line DLj of the data lines. The sub-pixel circuit SPC may be configured to control the light-emitting element LD in response to the signals received through these signal lines.

The sub-pixel circuit SPC may operate in response to a gate signal received through the i-th gate line GLi. The i-th gate line GLi may include one or more sub-gate lines. In an embodiment, if the i-th gate line GLi includes two or more sub-gate lines as shown in FIG. 3, the sub-pixel circuit SPC may operate in response to gate signals received through the corresponding sub-gate lines.

The sub-pixel circuit SPC may operate in response to a light emission control signal received through the i-th light emission control line ELi. In an embodiment, the i-th light emission control line ELi may include one or more sub-light-emission control lines. If the i-th light emission control line ELi includes two or more sub-light-emission control lines, the sub-pixel circuit SPC may operate in response to light emission control signals received through the corresponding sub-light-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the light emission control signal received through the i-th light emission control line ELi, the sub-pixel circuit SPC may adjust the current flowing from the first power supply voltage node VDDN to the second power supply voltage node VSSN via the light-emitting element LD according to the stored voltage. Accordingly, the light-emitting element LD can generate (or emit) light with a brightness corresponding to the data signal.

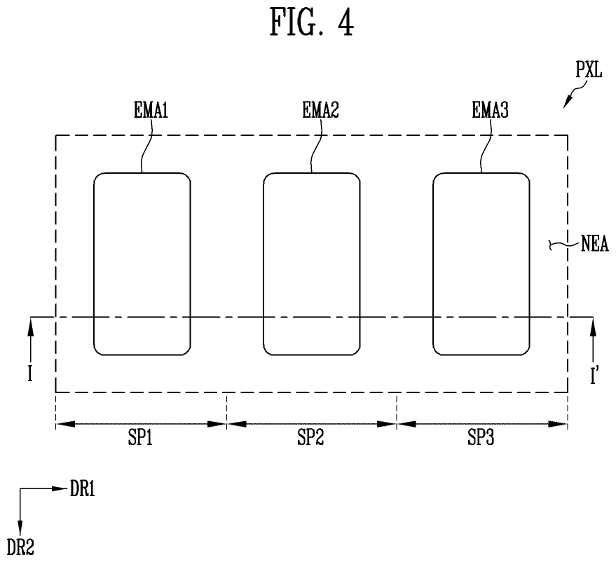

FIG. 4 is a schematic plan view showing the pixel PXL in FIG. 2.

Referring to FIG. 2 and FIG. 4, the pixel PXL may include a first sub-pixel SP1, a second sub-pixel SP2, and a third sub-pixel SP3 arranged in the first direction DR1.

The first sub-pixel SP1 may include a first light-emitting area EMAl and a non-light-emitting area NEA surrounding the first light-emitting area EMA1. The second sub-pixel SP2 may include a second light-emitting area EMA2 and a non-light-emitting area NEA surrounding the second light-emitting area EMA2. The third sub-pixel SP3 may include a third light-emitting area EMA3 and a non-light-emitting area NEA surrounding the third light-emitting area EMA3.

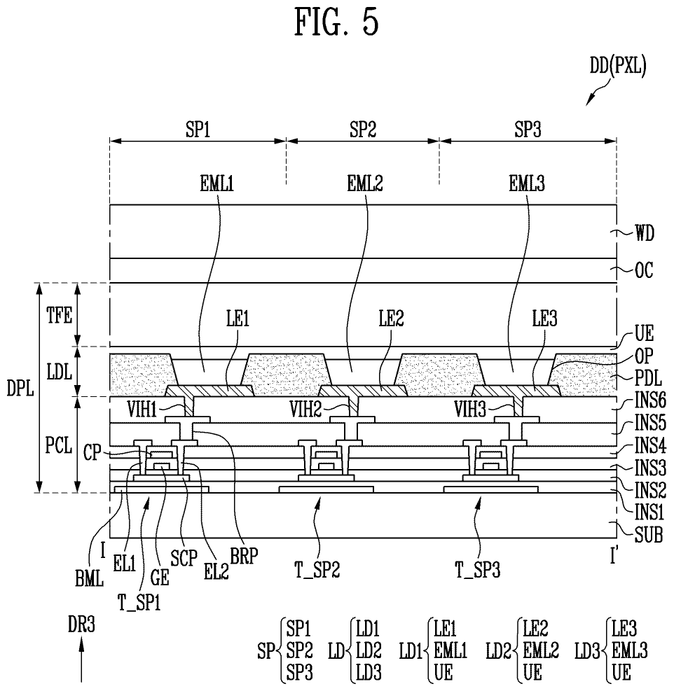

The first light-emitting area EMA1 may be an area where light is emitted from a light-emitting layer corresponding to the first sub-pixel SP1. The second light-emitting area EMA2 may be an area where light is emitted from a light-emitting layer corresponding to the second sub-pixel SP2. The third light-emitting area EMA3 may be an area where light is emitted from a light-emitting layer corresponding to the third sub-pixel SP3. Each light-emitting area may be understood as an opening (see “OP” in FIG. 5) of a pixel-defining film (see “PDL” in FIG. 5) corresponding to each of the first to third sub-pixels SP1 to SP3.

The first sub-pixel SP1, the second sub-pixel SP2, and the third sub-pixel SP3 may have substantially the same area, but the present disclosure is not limited thereto. According to an embodiment, the second sub-pixel SP2 may have a larger area than the first sub-pixel SP1, and the third sub-pixel SP3 may have a larger area than the second sub-pixel SP2.

The first sub-pixel SP1, the second sub-pixel SP2, and the third sub-pixel SP3 may have a polygonal shape. For example, the first sub-pixel SP1, the second sub-pixel SP2, and the third sub-pixel SP3 may have a polygonal shape or a hexagonal shape, but the present disclosure is not limited thereto. According to an embodiment, the first sub-pixel SP1, the second sub-pixel SP2, and the third sub-pixel SP3 may have a circular shape, a semi-elliptical shape, etc.

The arrangement of the sub-pixels shown in FIG. 4 is illustrative, and the present disclosure is not limited thereto. Each pixel PXL may include two or more sub-pixels, and the sub-pixels may be arranged in various ways. As each of the sub-pixels may have various shapes, each of the light-emitting areas of the sub-pixels may also have various shapes.

FIG. 5 is a schematic cross-sectional view taken along a line I-I′ in FIG. 4.

In FIG. 5, the cross-sectional structure (or stacked structure) of the display device DD is simply illustrated with a focus on the pixel PXL included in the display device DD, and the thickness direction of the substrate SUB is indicated as in the third direction DR3, for convenience of description.

Referring to FIG. 4 and FIG. 5, the display device DD may include at least one or more pixels PXL disposed in the display area (see “DA” in FIG. 2). The pixels PXL may be provided in a pixel area of the display area DA.

The pixel PXL may include at least one or more sub-pixels SP. For example, the pixel PXL may include a first sub-pixel SP1, a second sub-pixel SP2, and a third sub-pixel SP3. In an embodiment, the first sub-pixel SP1 may be a red sub-pixel, the second sub-pixel SP2 may be a green sub-pixel, and the third sub-pixel SP3 may be a blue sub-pixel, but the present disclosure is not limited thereto. In the following, when collectively referring to the first sub-pixel SP1, the second sub-pixel SP2, and the third sub-pixel SP3, they are referred to as the sub-pixel SP and/or sub-pixels SP.

Each of the first to third sub-pixels SP1 to SP3 may include a substrate SUB, a display element layer DPL, and a window WD.

The substrate SUB may include a transparent insulating material, allowing light to pass through. The substrate SUB may be a rigid substrate or a flexible substrate.

The display element layer DPL may be disposed on the substrate SUB. The display element layer DPL may include a pixel circuit layer PCL, a light-emitting element layer LDL, and a thin film encapsulation layer TFE. The pixel circuit layer PCL and the light-emitting element layer LDL may be disposed to overlap each other on the substrate SUB.

At least one or more insulating layers may be disposed on the pixel circuit layer PCL. For example, the insulating layers may include a first insulating layer INS1, a second insulating layer INS2, a third insulating layer INS3, a fourth insulating layer INS4, a fifth insulating layer INS5, and a sixth insulating layer INS6, which are stacked in sequence on the substrate SUB along the third direction DR3. The insulating layers disposed on the pixel circuit layer PCL are not limited to the embodiment described above, and other insulating layers may be added or some insulating layers may be omitted.

The first insulating layer INS1 (or a buffer layer) may be disposed on the substrate SUB. The first insulating layer INS1 may prevent impurities from diffusing into circuit elements (or driving elements) constituting the sub-pixel circuit (see “SPC” in FIG. 3), for example, transistors. The first insulating layer INS1 may be an inorganic insulating film containing an inorganic substance (or material). The first insulating layer INS1 may contain at least one of silicon nitride (SiNx), silicon oxide (SiOx), silicon oxynitride (SiOxNy), or aluminum oxide (AlOx). The first insulating layer INS1 may be provided as a single layer, but may also be provided as a multi-layer of at least two or more layers. The first insulating layer INS1 may be omitted depending on the material, process conditions, etc., of the substrate SUB.

The second insulating layer INS2 (or a first gate insulating layer) may be disposed on the first insulating layer INS1. The second insulating layer INS2 may contain the same material as the first insulating layer INS1 or may contain a suitable (or selected) material out of the materials exemplified as the constituent materials of the first insulating layer INS1. For example, the second insulating layer INS2 may be an inorganic film containing an inorganic material.

The third insulating layer INS3 (or a second gate insulating layer) may be disposed on the second insulating layer INS2. The third insulating layer INS3 may contain the same material as the first insulating layer INS1 or may contain one or more suitable (or selected) materials out of the materials exemplified as the constituent materials of the first insulating layer INS1.

The fourth insulating layer INS4 (or an interlayer insulating layer) may be disposed on the third insulating layer INS3. The fourth insulating layer INS4 may be an inorganic film containing an inorganic material or an organic film containing an organic material.

The fifth insulating layer INS5 (or a first via layer) may be disposed on the fourth insulating layer INS4. The fifth insulating layer INS5 may be an inorganic film containing an inorganic material or an organic film containing an organic material. The inorganic film may contain, for example, at least one of silicon oxide (SiOx), silicon nitride (SiNx), silicon oxynitride (SiOxNy), or aluminum oxide (AlOx). The organic film may contain, for example, at least one of polyacrylate resins, epoxy resins, phenolic resins, polyamide resins, polyimide resins, unsaturated polyester resins, poly-phenylene ether resins, poly-phenylene sulfide resins, or benzocyclobutene resins. In an embodiment, the fifth insulating layer INS5 may be an organic film.

The sixth insulating layer INS6 (or a second via layer) may be disposed on the fifth insulating layer INS5. The sixth insulating layer INS6 may contain the same material as the fifth insulating layer INS5 or may contain one or more suitable (or selected) materials out of the materials exemplified as the constituent materials of the first insulating layer INS1. For example, the sixth insulating layer INS6 may be an organic film containing an organic material.

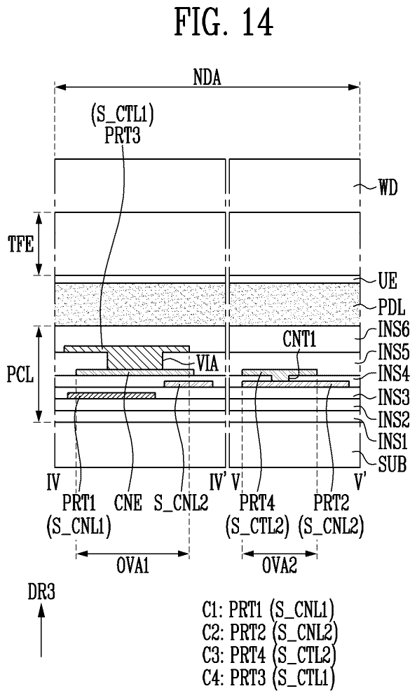

The pixel circuit layer PCL may include at least one or more conductive layers disposed between the insulating layers described above. For example, the conductive layers may include a first conductive layer (see “C1” in FIG. 14) disposed between the second insulating layer INS2 and the third insulating layer INS3, a second conductive layer (see “C2” in FIG. 14) disposed between the third insulating layer INS3 and the fourth insulating layer INS4, a third conductive layer (see “C3” in FIG. 14) disposed between the fourth insulating layer INS4 and the fifth insulating layer INS5, and a fourth conductive layer (see “C4” in FIG. 14) disposed between the fifth insulating layer INS5 and the sixth insulating layer INS6. The insulating layers and the conductive layers are not limited to the embodiment described above, and other insulating layers and other conductive layers may also be disposed in the pixel circuit layer PCL in addition to the insulating layers and conductive layers described above, depending on embodiments.

Circuit elements (or driving elements) of each of the first to third sub-pixels SP1 to SP3 may be disposed in the pixel circuit layer PCL. For example, a transistor T_SP1 of the first sub-pixel SP1, a transistor T_SP2 of the second sub-pixel SP2, and a transistor T_SP3 of the third sub-pixel SP3 may be disposed in the pixel circuit layer PCL. The transistor T_SP1 of the first sub-pixel SP1 may be one of the transistors included in the sub-pixel circuit SPC of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 5, one of the transistors of each sub-pixel SP is shown, and the rest of the circuit elements are omitted, for clear and concise description.

The transistor T_SP1 of the first sub-pixel SP1 may include a semiconductor pattern SCP, a gate electrode GE, a first terminal EL1, and a second terminal EL2.

The gate electrode GE may be disposed on the second insulating layer INS2 and covered by the third insulating layer INS3. For example, the gate electrode GE may be the first conductive layer C1 (or a first gate conductive layer) located between the second insulating layer INS2 and the third insulating layer INS3. The gate electrode GE may overlap a part of the semiconductor pattern SCP. For example, the gate electrode GE may overlap an active pattern of the semiconductor pattern SCP.

The pixel circuit layer PCL may include a conductive pattern CP disposed between the third insulating layer INS3 and the fourth insulating layer INS4. The conductive pattern CP may be formed of the second conductive layer C2 (or a second gate conductive layer). According to an embodiment, the conductive pattern CP may also overlap the gate electrode GE with the third insulating layer INS3 interposed therebetween, thereby forming a capacitor.

The semiconductor pattern SCP may be disposed on the first insulating layer INS1 and covered by the second insulating layer INS2. The semiconductor pattern SCP may be a semiconductor layer made of polysilicon, amorphous silicon, an oxide semiconductor, or the like. The semiconductor pattern SCP may include an active pattern, a first contact area, and a second contact area. The active pattern, the first contact area, and the second contact area may be formed of a semiconductor layer that is not doped with impurities or doped with impurities. For example, the first contact area and the second contact area may be formed of a semiconductor layer that is doped with impurities, and the active pattern may be formed of a semiconductor layer that is not doped with impurities. The active pattern may be an area that is doped at a lower concentration than the first and second contact areas. Accordingly, the conductivity of the first and second contact areas may be greater than the conductivity of the active pattern. The first and second contact areas may be source/drain areas (or source/drain electrodes) of the transistor T_SP1 of the first sub-pixel SP1.

The active pattern of the semiconductor pattern SCP may be an area overlapping the gate electrode GE and may be a channel area. The first contact area of the semiconductor pattern SCP may be formed in a first portion of the semiconductor pattern. The first contact area may be electrically connected to the first terminal EL1. The second contact area of the semiconductor pattern SCP may be formed in a second portion of the semiconductor pattern, which is an opposite side to the first side with respect to the active pattern. The second contact area may be electrically connected to the second terminal EL2.

The first terminal EL1 may be formed on the fourth insulating layer INS4. For example, the first terminal EL1 may be formed of the third conductive layer C3 (or a first source-drain conductive layer) which is disposed between the fourth insulating layer INS4 and the fifth insulating layer INS5. The first terminal EL1 may contact the first contact area of the semiconductor pattern SCP through a contact hole extending through the fourth insulating layer INS4, the third insulating layer INS3, and the second insulating layer INS2.

The second terminal EL2 may be formed on the fourth insulating layer INS4. The second terminal EL2 may be formed of the third conductive layer C3 which is disposed between the fourth insulating layer INS4 and the fifth insulating layer INS5. The second terminal EL2 may contact the second contact area of the semiconductor pattern SCP through another contact hole extending through the fourth insulating layer INS4, the third insulating layer INS3, and the second insulating layer INS2.

The second terminal EL2 may be electrically connected to a bridge pattern BRP disposed on the fifth insulating layer INS5. The bridge pattern BRP may be the fourth conductive layer C4 (or a second source-drain conductive layer) which is disposed between the fifth insulating layer INS5 and the sixth insulating layer INS6.

According to an embodiment, a bottom metal pattern BML may be disposed under the transistor T_SP1 of the first sub-pixel SP1 described above.

The bottom metal pattern BML may be a dummy conductive layer located between the substrate SUB and the first insulating layer INS1. According to an embodiment, the bottom metal pattern BML may be electrically connected to the transistor T_SP1 of the first sub-pixel SP1 and widen the driving range of the voltage supplied to the gate electrode GE.

As the gate electrode GE, the first terminal EL1, and the second terminal EL2 are electrically connected to other circuit elements and/or wiring lines, the transistor T_SP1 of the first sub-pixel SP1 may be provided as one of the transistors constituting the sub-pixel circuit SPC of the first sub-pixel SP1.

Each of the transistor T_SP2 of the second sub-pixel SP2 and the transistor T_SP3 of the third sub-pixel SP3 may be configured substantially the same as the transistor T_SP1 of the first sub-pixel SP1.

As described above, the pixel circuit layer PCL may include circuit elements of each of the first to third sub-pixels SP1 to SP3.

The light-emitting element layer LDL may be disposed on the pixel circuit layer PCL. The light-emitting element layer LDL may include a light-emitting element LD and a pixel-defining film PDL. The light-emitting element LD may include a lower electrode LE, a light-emitting layer EML, and an upper electrode UE. The light-emitting element LD may be provided in each of the first to third sub-pixels SP1 to SP3. The light-emitting element LD provided in the first sub-pixel SP1 may be a first light-emitting element LD1, the light-emitting element LD provided in the second sub-pixel SP2 may be a second light-emitting element LD2, and the light-emitting element LD provided in the third sub-pixel SP3 may be a third light-emitting element LD3.

A first lower electrode LEI may be disposed on the pixel circuit layer PCL (or the sixth insulating layer INS6) of the first sub-pixel SP1, a second lower electrode LE2 may be disposed on the pixel circuit layer PCL (or the sixth insulating layer INS6) of the second sub-pixel SP2, and a third lower electrode LE3 may be disposed on the pixel circuit layer PCL (or the sixth insulating layer INS6) of the third sub-pixel SP3. Each of the first to third lower electrodes LE1 to LE3 may be electrically connected to a circuit element disposed on the pixel circuit layer PCL through a via hole extending through the sixth insulating layer INS6. For example, the first lower electrode LE1 may be electrically connected to the transistor T_SP1 of the first sub-pixel SP1 through a first via hole VIH1 extending through the sixth insulating layer INS6, the second lower electrode LE2 may be electrically connected to the transistor T_SP2 of the second sub-pixel SP2 through a second via hole VIH2 extending through the sixth insulating layer INS6, and the third lower electrode LE3 may be electrically connected to the transistor T_SP3 of the third sub-pixel SP3 through a third via hole VIH3 extending through the sixth insulating layer INS6.

In an embodiment, the first lower electrode LE1, the second lower electrode LE2, and the third lower electrode LE3 may be anode electrodes. Each of the first to third lower electrodes LE1 to LE3 may have a shape similar to the first to third light-emitting areas EMA1 to EMA3 in FIG. 4 when viewed from the third direction DR3. For example, the first lower electrode LE1 may have a shape similar to the first light-emitting area EMA1 when viewed from the third direction DR3, the second lower electrode LE2 may have a shape similar to the second light-emitting area EMA2 when viewed from the third direction DR3, and the third lower electrode LE3 may have a shape similar to the third light-emitting area EMA3 when viewed from the third direction DR3, but the present disclosure is not limited thereto.

Each of the first to third lower electrodes LEI to LE3 may be electrically connected to a corresponding sub-pixel circuit SPC and be supplied with a driving current. Each of the first to third lower electrodes LEI to LE3 may include an opaque conductive material capable of reflecting light, but the present disclosure is not limited thereto. According to an embodiment, the first to third lower electrodes LE1 to LE3 may include a transparent conductive material.

The pixel-defining film PDL may be located on the first to third lower electrodes LE1 to LE3. The pixel-defining film PDL may include openings OP that extend to a portion of the first lower electrode LE1, a portion of the second lower electrode LE2, and a portion of the third lower electrode LE3. The pixel-defining film PDL may be a structure that defines (or divides) a light-emitting area of each of the first to third sub-pixels SP1 to SP3. For example, the pixel-defining film PDL may define the first light-emitting area EMA1 of the first sub-pixel SP1, the second light-emitting area EMA2 of the second sub-pixel SP2, and the third light-emitting area EMA3 of the third sub-pixel SP3.

The pixel-defining film PDL may be formed of an organic insulating film containing an organic material. The organic material (or organic substance) may include acrylic resins, epoxy resins, phenolic resins, polyamide resins, polyimide resins, etc. According to an embodiment, the pixel-defining film PDL may include a light-absorbing material, or may be coated with a light-absorbing agent to thereby absorb light incident from the outside. For example, the pixel-defining film PDL may include a carbon-based black pigment. However, the present disclosure is not limited thereto.

A first light-emitting layer EML1 may be disposed on the first lower electrode LE1 exposed by an opening OP of the pixel-defining film PDL, a second light-emitting layer EML2 may be disposed on the second lower electrode LE2 exposed by another opening OP of the pixel-defining film PDL, and a third light-emitting layer EML3 may be disposed on the third lower electrode LE3 exposed by yet another opening OP of the pixel-defining film PDL. Each of the first to third light-emitting layers EML1, EML2, and EML3 may have a multi-layer structure including a hole injection layer, a hole transport layer, an organic light-emitting layer, an electron transport layer, an electron injection layer, or the combination thereof.

The first to third light-emitting layers EML1 to EML3 may include at least one of the light-emitting materials that emit light of different colors depending on the corresponding sub-pixel SP. For example, the first light-emitting layer EML1 may include at least one of the light-emitting materials that emit red light, the second light-emitting layer EML2 may include at least one of the light-emitting materials that emit green light, and the third light-emitting layer EML3 may include at least one of the light-emitting materials that emit blue light. However, the present disclosure is not limited thereto, and according to an embodiment, each of the first to third light-emitting layers EML1 to EML3 may emit white light as a whole by stacking a plurality of light-emitting materials that generate lights of different colors, such as red light, green light, and blue light. In this case, a color filter may be further disposed, respectively, on the first to third light-emitting layers EML1 to EML3. The color filter may include at least one of a red color filter, a green color filter, or a blue color filter.

The upper electrode UE may be disposed on the first to third light-emitting layers EML1, EML2, and EML3 and the pixel-defining film PDL. In an embodiment, the upper electrode UE may be a cathode electrode. The upper electrode UE may be a common layer provided in common to the first to third sub-pixels SP1 to SP3. The upper electrode UE may be provided in the form of a plate over the entire area of the display area DA. According to an embodiment, the upper electrode UE may function as a half mirror that partially transmits and partially reflects light emitted from a corresponding light-emitting layer.

The upper electrode UE may be a thin metal layer having a thickness sufficient to transmit light emitted from a corresponding light-emitting layer. The upper electrode UE may be formed of a metallic material or a transparent conductive material to have a relatively thin thickness. In an embodiment, the upper electrode UE may include at least one of a variety of transparent conductive materials, including indium tin oxide, indium zinc oxide, indium tin zinc oxide, aluminum zinc oxide, gallium zinc oxide, zinc tin oxide, or gallium tin oxide. In an embodiment, the upper electrode UE may include at least one of magnesium, silver, or mixtures thereof. However, the material of the upper electrode UE is not limited to the embodiments described above.

The first lower electrode LE1, the first light-emitting layer EML1, and the portion of the upper electrode UE overlapping the first lower electrode LE1 may constitute the first light-emitting element LD1. The second lower electrode LE2, the second light-emitting layer EML2, and the portion of the upper electrode UE overlapping the second lower electrode LE2 may constitute the second light-emitting element LD2. The third lower electrode LE3, the third light-emitting layer EML3, and the portion of the upper electrode UE overlapping the third lower electrode LE3 may constitute the third light-emitting element LD3.

The thin film encapsulation layer TFE may be disposed on the upper electrode UE. The thin film encapsulation layer TFE may cover the light-emitting element layer LDL. The thin film encapsulation layer TFE may be configured to prevent oxygen and/or moisture, etc., from infiltrating into the light-emitting element layer LDL. In an embodiment, the thin film encapsulation layer TFE may include a structure in which one or more inorganic films and one or more organic films are stacked alternately. For example, the inorganic film may contain silicon nitride, silicon oxide, silicon oxynitride, or the like. For example, the organic film may contain organic insulating materials, such as polyacrylate resins, epoxy resins, phenolic resins, polyamide resins, polyimide resins, unsaturated polyester resins, poly-phenylene resins, poly-phenylene sulfide resins, or benzocyclobutene. However, the materials of the organic film and inorganic film of the thin film encapsulation layer TFE are not limited thereto.

An overcoat layer OC may be disposed on the thin film encapsulation layer TFE. The overcoat layer OC may be a material with excellent light transmittance. The overcoat layer OC may flatten the top of the thin film encapsulation layer TFE. The overcoat layer OC may be made of a polyacrylate epoxy material, but the present disclosure is not limited thereto.

The window WD may be disposed on top of the overcoat layer OC. The window WD may be a protective member that is disposed on top of the overcoat layer OC and protects the components of the display device DD. The window WD may be glass or plastic. When the window WD includes glass, it may be made of ultra-thin glass (UTG) having a thickness of 0.1 mm or less in order to have a flexible characteristic, but the present disclosure is not limited thereto. In an embodiment, the window WD may have a thickness of approximately 385 μm along the third direction DR3, but is not limited thereto. According to an embodiment, a polarizing member may be disposed between the window WD and the overcoat layer OC.

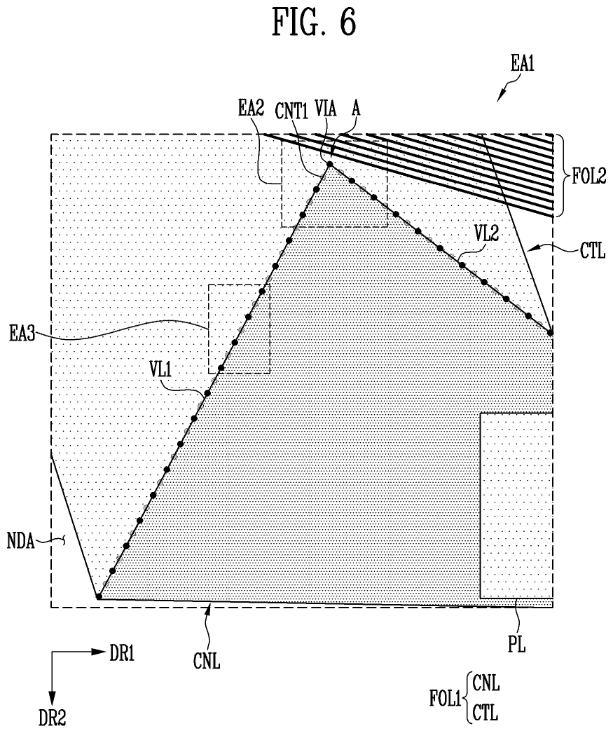

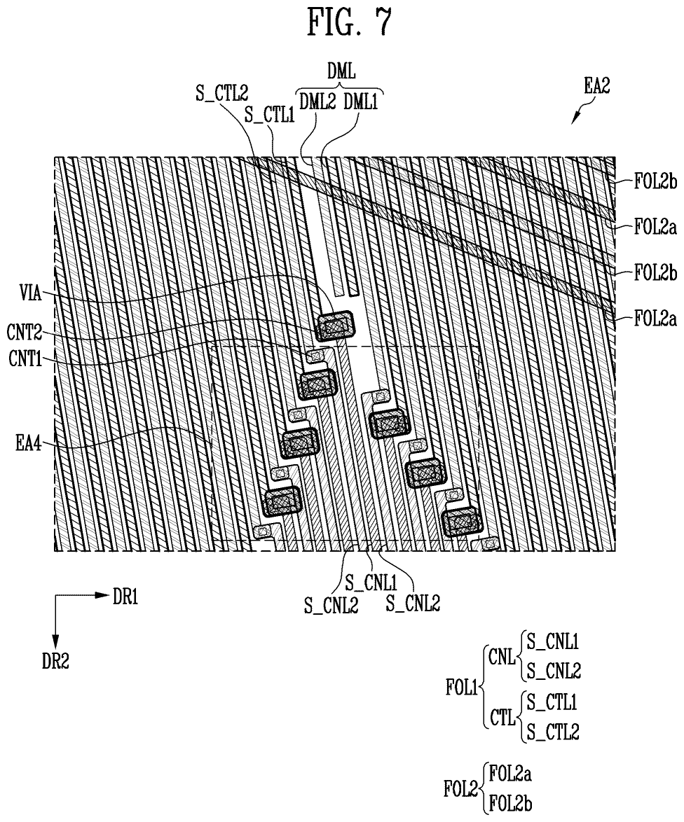

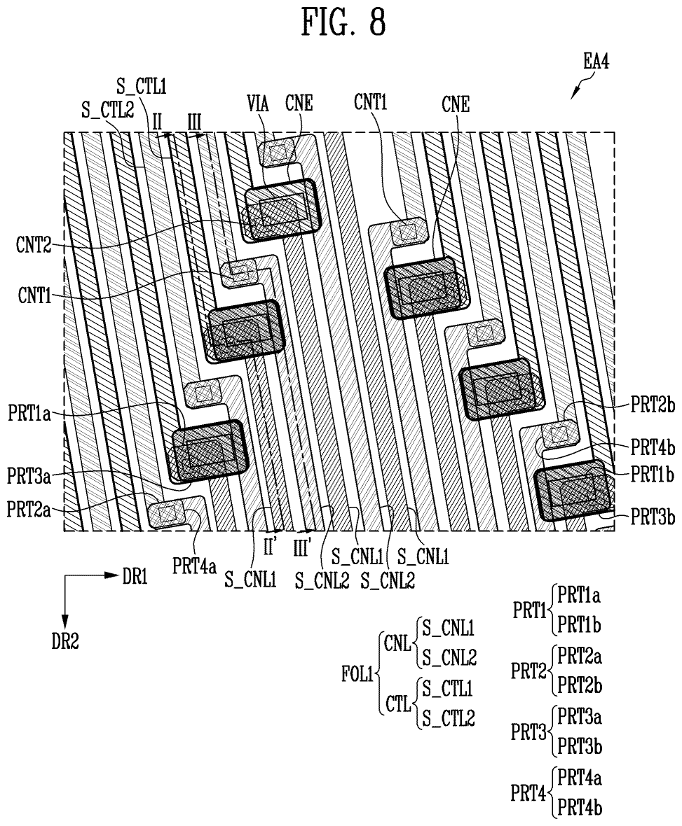

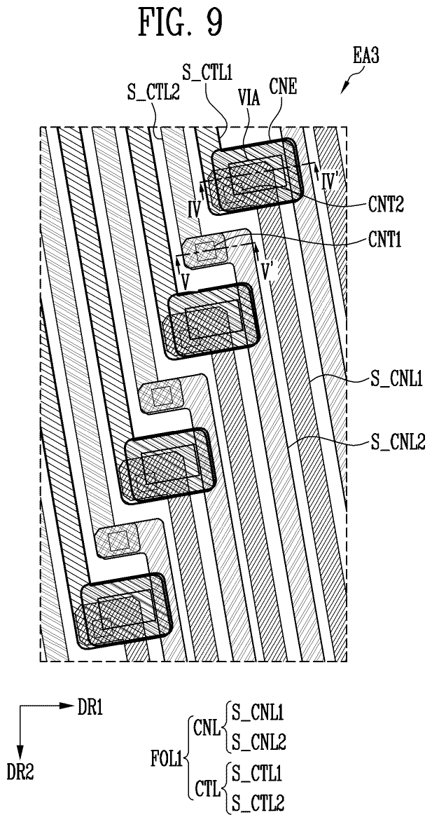

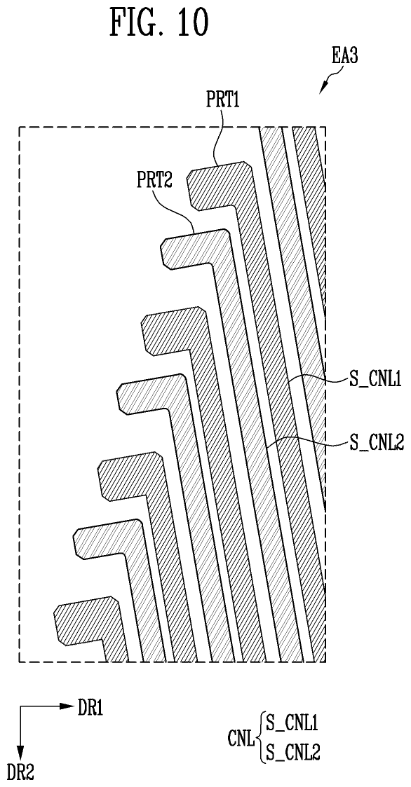

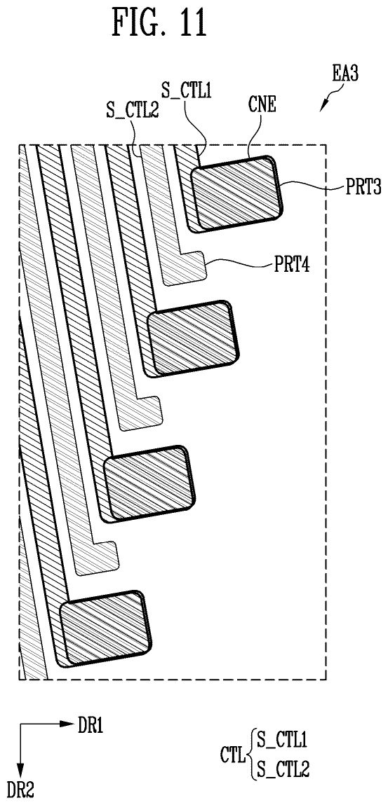

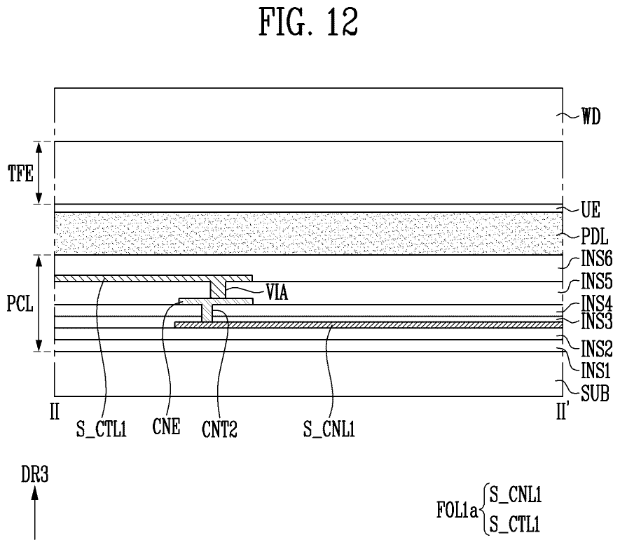

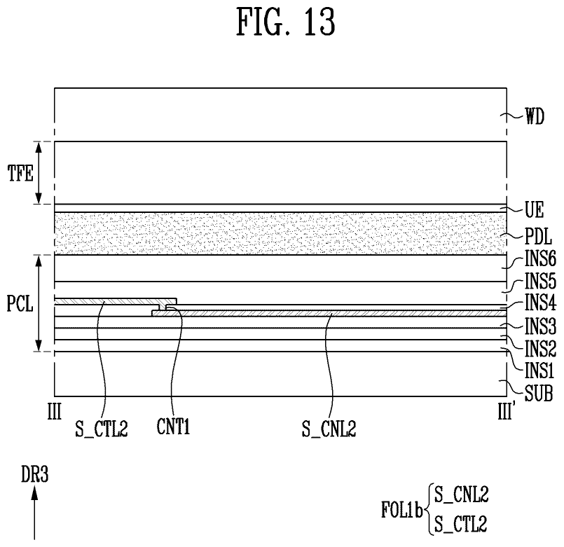

FIG. 6 is a schematic plan view showing an enlarged view of the area EA1 in FIG. 2, FIG. 7 is a schematic plan view showing an enlarged view of the area EA2 in FIG. 6 is enlarged, FIG. 8 is a schematic plan view showing an enlarged view of the area EA4 in FIG. 7, and FIG. 9 is a schematic plan view showing an enlarged view of the area EA3 in FIG. 6. FIG. 10 is a schematic plan view illustrating the first sub-connection wiring line S_CNL1 and the second sub-connection wiring line S_CNL2 in FIG. 9, FIG. 11 is a schematic plan view illustrating the first sub-intermediate wiring line S_CTL1 and the second sub-intermediate wiring line S_CTL2 in FIG. 9, FIG. 12 is a schematic cross-sectional view taken along a line II-II′ in FIG. 8, FIG. 13 is a schematic cross-sectional view taken along a line III-III′ in FIG. 8, and FIG. 14 is a schematic cross-sectional view taken along lines IV-IV′ and V-V′ in FIG. 9.

In describing FIGS. 6 to 14, differences from an embodiment described above will be mainly described in order to avoid repetitive descriptions.

Referring to FIGS. 2 and 6 to 14, the substrate SUB, the pixel circuit layer PCL, the pixel-defining film PDL, the upper electrode UE, the thin film encapsulation layer TFE, and the window WD may be located in the non-display area NDA.

The first to sixth insulating layers INS1 to INS6 described with reference to FIG. 5 may be disposed in the pixel circuit layer PCL. The pixel-defining film PDL and the upper electrode UE described with reference to FIG. 5 may be disposed on the pixel circuit layer PCL. The thin film encapsulation layer TFE described with reference to FIG. 5 may be disposed on the upper electrode UE. The window WD described with reference to FIG. 5 may be disposed on the thin film encapsulation layer TFE. Although not directly shown in FIGS. 12 to 14, the overcoat layer OC described with reference to FIG. 5 may be disposed between the thin film encapsulation layer TFE and the window WD.

The first fan-out line FOL1 and the second fan-out line FOL2 may be disposed on the pixel circuit layer PCL of the non-display area NDA.

The second fan-out line FOL2 may include a 2a fan-out line FOL2a and a 2b fan-out line FOL2b disposed on different layers. The 2a fan-out line FOL2a may be formed of the first conductive layer (see “C1” in FIG. 14). The 2b fan-out line FOL2b may be formed of the second conductive layer (see “C2” in FIG. 14).

The first fan-out line FOL1 may include a connection wiring line CNL extending from the pad part (see “PDP” in FIG. 2) and an intermediate wiring line CTL electrically connecting the connection wiring line CNL to signal wiring lines disposed in the display area DA, for example, the data lines. The connection wiring line CNL and the intermediate wiring line CTL may be disposed on different layers and may partially overlap.

The connection wiring line CNL may overlap a power supply wiring line PL to which the first power supply voltage or the second power supply voltage is supplied. The power supply wiring line PL may not overlap the intermediate wiring line CTL and may be disposed on the same layer as the intermediate wiring line CTL.

The connection wiring line CNL may include a first sub-connection wiring line S_CNL1 and a second sub-connection wiring line S_CNL2 that are disposed spaced apart from each other. The first sub-connection wiring line S_CNL1 and the second sub-connection wiring line S_CNL2 may be provided in plurality.

The first sub-connection wiring line S_CNL1 and the second sub-connection wiring line S_CNL2 may be disposed on different layers. For example, the first sub-connection wiring line S_CNL1 may be formed of the first conductive layer C1 (or the first gate conductive layer) disposed between the second insulating layer INS2 and the third insulating layer INS3, and the second sub-connection wiring line S_CNL2 may be formed of the second conductive layer C2 (or the second gate conductive layer) disposed between the third insulating layer INS3 and the fourth insulating layer INS4. The first sub-connection wiring line S_CNL1 may be disposed on the same layer as the 2a fan-out line FOL2a, and the second sub-connection wiring line S_CNL2 may be disposed on the same layer as the 2b fan-out line FOL2b, but the present disclosure is not limited thereto. According to an embodiment, the first sub-connection wiring line S_CNL1 may be disposed on the same layer as the 2b fan-out line FOL2b, and the second sub-connection wiring line S_CNL2 may be disposed on the same layer as the 2a fan-out line FOL2a. The first and second sub-connection wiring lines S_CNL1 and S_CNL2 may not overlap the second fan-out line FOL2 and may be electrically isolated from the second fan-out line FOL2.

The first sub-connection wiring line S_CNL1 and the second sub-connection wiring line S_CNL2 may be bent at least once or more, but the present disclosure is not limited thereto. A part of each of the first and second sub-connection wiring lines S_CNL1 and S_CNL2 may extend in one direction inclined to the second direction DR2.

As shown in FIG. 10, the first sub-connection wiring lines S_CNL1 and the second sub-connection wiring lines S_CNL2 may be arranged alternately along the first direction DR1. For example, one second sub-connection wiring line S_CNL2 may be disposed between two adjacent first sub-connection wiring lines S_CNL1. Further, one first sub-connection wiring line S_CNL1 may be disposed between two adjacent second sub-connection wiring lines S_CNL2. The first sub-connection wiring lines S_CNL1 and the second sub-connection wiring lines S_CNL2 may be electrically isolated from each other.

An end of each of the first and second sub-connection wiring lines S_CNL1 and S_CNL2 may overlap with an end of a corresponding intermediate wiring line CTL. Each of the first and second sub-connection wiring lines S_CNL1 and S_CNL2 may be electrically connected to a corresponding intermediate wiring line CTL.

The intermediate wiring line CTL may include a first sub-intermediate wiring line S_CTL1 and a second sub-intermediate wiring line S_CTL2 that are disposed spaced apart from each other. The first sub-intermediate wiring line S_CTL1 and the second sub-intermediate wiring line S_CTL2 may be provided in plurality.

The first sub-intermediate wiring line S_CTL1 and the second sub-intermediate wiring line S_CTL2 may be disposed on different layers. For example, the first sub-intermediate wiring line S_CTL1 may be formed of the fourth conductive layer (see “C4’ in FIG. 14) (or the second source-drain conductive layer) disposed between the fifth insulating layer INS5 and the sixth insulating layer INS6, and the second sub-intermediate wiring line S_CTL2 may be formed of the third conductive layer (see “C3” in FIG. 14) (or the first source-drain conductive layer) disposed between the fourth insulating layer INS4 and the fifth insulating layer INS5. The first and second sub-intermediate wiring lines S_CTL1 and S_CTL2 may partially overlap the second fan-out line FOL2.

The first sub-intermediate wiring line S_CTL1 and the second sub-intermediate wiring line S_CTL2 may be bent at least once or more, but the present disclosure is not limited thereto. A part of each of the first and second sub-intermediate wiring lines S_CTL1 and S_CTL2 may extend in one direction inclined to the second direction DR2.

As shown in FIG. 11, the first sub-intermediate wiring lines S_CTL1 and the second sub-intermediate wiring lines S_CTL2 may be arranged alternately along the first direction DR1. For example, one second sub-intermediate wiring line S_CTL2 may be disposed between two adjacent first sub-intermediate wiring lines S_CTL1. Further, one first sub-intermediate wiring line S_CTL1 may be disposed between two adjacent second sub-intermediate wiring lines S_CTL2. The first sub-intermediate wiring lines S_CTL1 and the second sub-intermediate wiring lines S_CTL2 may be electrically isolated from each other.

An end of each of the first and second sub-intermediate wiring lines S_CTL1 and S_CTL2 may overlap an end of a corresponding connection wiring line CNL. Each of the first and second sub-intermediate wiring lines S_CTL1 and S_CTL2 may be electrically connected to the first sub-connection wiring S_CNL1 and the second sub-connection wiring S_CNL2, respectively.

The end of the first sub-connection wiring line S_CNL1 may be provided with a first protrusion PRT1 protruding in a direction intersecting the extension direction of the first sub-connection wiring line S_CNL1. The end of the second sub-connection wiring line S_CNL2 may be provided with a second protrusion PRT2 protruding in a direction intersecting the extension direction of the second sub-connection wiring line S_CNL2. The end of the first sub-intermediate wiring line S_CTL1 may be provided with a third protrusion PRT3 protruding in a direction intersecting the extension direction of the first sub-intermediate wiring line S_CTL1. The end of the second sub-intermediate wiring line S_CTL2 may be provided with a fourth protrusion PRT4 protruding in a direction intersecting the extension direction of the second sub-intermediate wiring line S_CTL2.

The first protrusion PRT1 formed of the first conductive layer Cl and the third protrusion PRT3 formed of the fourth conductive layer C4 may overlap each other, and the second protrusion PRT2 formed of the second conductive layer C2 and the fourth protrusion PRT4 formed of the third conductive layer C3 may overlap each other.

As shown in FIG. 12 and FIG. 13, the first sub-connection wiring line S_CNL1 may be electrically connected to the first sub-intermediate wiring line S_CTL1 through a via VIA and a contact electrode CNE. The second sub-connection wiring line S_CNL2 may be electrically connected to the second sub-intermediate wiring line S_CTL2 through a first contact hole CNT1.

The contact electrode CNE may be formed of the third conductive layer C3, may be formed in the same process as the second sub-intermediate wiring line S_CTL2, and may be disposed on the same layer as the second sub-intermediate wiring line S_CTL2. For example, the contact electrode CNE may be disposed on the fourth insulating layer INS4. The contact electrode CNE and the second sub-intermediate wiring line S_CTL2 may be disposed spaced apart from each other and may be electrically isolated from each other. The contact electrode CNE may be located between the first protrusion PRT1 of the first sub-connection wiring line S_CNL1 and the third protrusion PRT3 of the first sub-intermediate wiring line S_CTL1, and may overlap the first and third protrusions PRT1 and PRT3. In other words, the contact electrode CNE may be located in a first overlap area OVA1 where the first protrusion PRT1 and the third protrusion PRT3 overlap.

The contact electrode CNE may have a part thereof exposed by a via VIA of the fifth insulating layer INS5. The via VIA may be an opening area formed by removing a part of the fifth insulating layer INS5. The third protrusion PRT3 (or the first sub-intermediate wiring line S_CTL1) may be electrically connected to the contact electrode CNE through the via VIA. Further, the contact electrode CNE may be electrically connected to the first protrusion PRT1 (or the first sub-connection wiring line S_CNL1) through a second contact hole CNT2 that extends through the fourth insulating layer INS4, and the third insulating layer INS3. Each of the plurality of first sub-intermediate wiring lines S_CTL1 may be electrically connected to a corresponding first sub-connection wiring line S_CNL1 through the via VIA, the contact electrode CNE, and the second contact hole CNT2. As described above, the first sub-intermediate wiring line S_CTL1 and the first sub-connection wiring line S_CNL1 that are electrically connected may constitute a 1a fan-out line FOL1a of the first fan-out line FOL1.

The fourth protrusion PRT4 (or the second sub-intermediate wiring line S_CTL2) may be directly connected to the second protrusion PRT2 (or the second sub-connection wiring line S_CNL2) through the first contact hole CNT1 that extends through the fourth insulating layer INS4. Each of the plurality of second sub-intermediate wiring lines S_CTL2 may be directly connected to a corresponding second sub-connection wiring line S_CNL2 through the first contact hole CNT1. As described above, the second sub-intermediate wiring line S_CTL2 and the second sub-connection wiring line S_CNL2 that are connected electrically and physically may constitute a 1b fan-out line FOL1b of the first fan-out line FOL1.

The first overlap area OVA1 where the first protrusion PRT1 and the third protrusion PRT3 overlap may correspond to an electrical connection point between the first sub-connection wiring line S_CNL1 and the first sub-intermediate wiring line S_CTL1. A second overlap area OVA2 where the second protrusion PRT2 and the third protrusion PRT3 overlap may correspond to an electrical connection point between the second sub-connection wiring line S_CNL2 and the second sub-intermediate wiring line S_CTL2.

In an embodiment, the vias VIA may be provided in plurality, and the first contact holes CNT1 may also be provided in plurality. The plurality of vias VIA and the plurality of first contact holes CNT1 may be arranged along a direction inclined to the extension direction of the connection wiring line CNL and the intermediate wiring line CTL in a plan view.

In a plan view, the plurality of vias VIA and the plurality of first contact holes CNT1 may be disposed alternately with each other along the first direction DR1. For example, one first contact hole CNT1 may be disposed between two adjacent vias VIA. Further, one via VIA may be disposed between two adjacent first contact holes CNT1.

In a plan view, some of the plurality of vias VIA and some of the plurality of first contact holes CNT1 may be arranged along a first virtual line VL1 extending in a first inclined direction inclined to the extension direction of the intermediate wiring line CTL and the connection wiring line CNL. For example, as shown in FIG. 6, some vias VIA located on the left side among the plurality of vias VIA and some first contact holes CNT1 located on the left side among the plurality of first contact holes CNT1 may be arranged along the first virtual line VL1. In addition, the rest of the plurality of vias VIA and the rest of the plurality of first contact holes CNT1 may be arranged along a second virtual line VL2, which is extending in a second inclined direction and faces the first inclined direction. For example, as shown in FIG. 6, the rest of the vias VIA located on the right side among the plurality of vias VIA and the rest of the first contact holes CNT1 located on the right side among the plurality of first contact holes CNT1 may be arranged along the second virtual line VL2.

In an embodiment, the plurality of vias VIA and the plurality of first contact holes CNT1 arranged along the first virtual line VL1 and the second virtual line VL2 may form a single wedge shape in a plan view. In other words, the first virtual line VL1 and the second virtual line VL2 may be connected to form a single wedge shape, but the present disclosure is not limited thereto. The single wedge shape may be implemented in an “A shape” in a plan view.

As shown in FIG. 7, a dummy pattern DML may be disposed near the vertex A of the wedge shape. The dummy pattern DML may include a first dummy pattern DML1 and a second dummy pattern DML2 that are disposed spaced apart from each other in a plan view. The first dummy pattern DML1 may be disposed on the same layer as the first sub-intermediate wiring line S_CTL1. For example, the first dummy pattern DML1 may be formed of the fourth conductive layer C4. The second dummy pattern DML2 may be disposed on the same layer as the second sub-intermediate wiring line S_CTL2. For example, the second dummy pattern DML2 may be formed of the third conductive layer C3.

The first dummy pattern DML1 and the second dummy pattern DML2 may be electrically isolated from the connection wiring line CNL and the intermediate wiring line CTL. The first dummy pattern DML1 and the second dummy pattern DML2 may be disposed near the vertex A of the wedge shape in order to compensate for the density difference of the wiring line and/or pattern in an area of the non-display area NDA where the first fan-out line FOL is located.

As shown in FIG. 8, the first protrusion PRT1 may include a 1a protrusion PRT1a arranged along the first inclined direction (or the extension direction of the first virtual line VL1) inclined to the extension direction of the first sub-connection wiring line S_CNL1, and a 1b protrusion PRT1b arranged along the second inclined direction (or the extension direction of the second virtual line VL2) facing the first inclined direction. In a plan view, the 1a protrusion PRT1a and the 1b protrusion PRT1b may protrude in opposite directions to each other. For example, the 1a protrusion PRT1a may protrude in the left direction, and the 1b protrusion PRT1b may protrude in the right direction, as shown in FIG. 8.

The second protrusion PRT2 may include a 2a protrusion PRT2a arranged along the first inclined direction (or the extension direction of the first virtual line VL1) inclined to the extension direction of the second sub-connection wiring line S_CNL2, and a 2b protrusion PRT2b arranged along the second inclined direction (or the extension direction of the second virtual line VL2) facing the first inclined direction. In a plan view, the 2a protrusion PRT2a and the 2b protrusion PRT2b may protrude in opposite directions to each other. For example, the 2a protrusion PRT2a may protrude in the left direction, and the 2b protrusion PRT2b may protrude in the right direction, as shown in FIG. 8.

The third protrusion PRT3 may include a 3a protrusion PRT3a arranged along the first inclined direction (or the extension direction of the first virtual line VL1) inclined to the extension direction of the first sub-intermediate wiring line S_CTL1 and a 3b protrusion PRT3b arranged along the second inclined direction (or the extension direction of the second virtual line VL2) facing the first inclined direction. In a plan view, the 3a protrusion PRT3a and the 3b protrusion PRT3b may protrude in opposite directions to each other. For example, the 3a protrusion PRT3a may protrude in the right direction, and the 3b protrusion PRT3b may protrude in the left direction, as shown in FIG. 8.

The fourth protrusion PRT4 may include a 4a protrusion PRT4a arranged along the first inclined direction (or the extension direction of the first virtual line VL1) inclined to the extension direction of the second sub-intermediate wiring line S_CTL2 and a 4b protrusion PRT4b arranged along the second inclined direction (or the extension direction of the second virtual line VL2) facing the first inclined direction. In a plan view, the 4a protrusion PRT4a and the 4b protrusion PRT4b may protrude in opposite directions to each other. For example, the 4a protrusion PRT4a may protrude in the right direction, and the 4b protrusion PRT4b may protrude in the left direction, as shown in FIG. 8.

A via VIA may be disposed in each of the first overlap areas OVA1 where the first protrusion PRT1 and the third protrusion PRT3 overlap. In a plan view, the longitudinal direction of the via VIA may be parallel to the protrusion direction of each of the first and third protrusions PRT1 and PRT3. In other words, in a plan view, the longitudinal direction of the via VIA may be parallel to one direction intersecting the extension direction of each of the first sub-connection wiring line S_CNL1 and the first sub-intermediate wiring line S_CTL1.

According to an embodiment described above, as the end of the first sub-connection wiring line S_CNL1 has the first protrusion PRT1 protruding in one direction intersecting its extension direction and the end of the first sub-intermediate wiring line S_CTL1 has the third protrusion PRT3 protruding in one direction intersecting its extension direction, a via VIA can be located in the first overlap area OVAL where the first protrusion PRT1 and the third protrusion PRT3 overlap. As a result, the via VIA may be arranged along one direction intersecting the extension directions of the first sub-connection wiring line S_CNL1 and the first sub-intermediate wiring line S_CTL1, for example, a diagonal direction. In this case, the via VIA may not be affected by the extension direction of the first sub-connection wiring line S_CNL1 and the first sub-intermediate wiring line S_CTL1. Accordingly, it is possible to reduce the design constraints required to secure the spacing between adjacent vias VIA, for example, design constraints such to maintain the spacing between adjacent first sub-connection wiring lines S_CNL1, the spacing between adjacent second sub-connection wiring lines S_CNL2, the spacing between adjacent first sub-intermediate wiring lines S_CTL1, and the spacing between adjacent second sub-intermediate wiring lines S_CTL2 at a certain level or higher.

According to an embodiment described above, as the via VIA located at the connection point (or the first overlap area OVA1) between the first sub-connection wiring line S_CNL1 and the first sub-intermediate wiring line S_CTL1, and the first contact hole CNT1 located at the connection point (or the second overlap area OVA2) between the second sub-connection wiring line S_CNL2 and the second sub-intermediate wiring line S_CTL2 are arranged along the first virtual line VL1 and the second virtual line VL2 to form a wedge shape, the spacing between the connection wiring line CNL and the second fan-out line FOL2, which are formed in the same process and disposed on the same layer, can be further secured. Accordingly, additional space may be secured for design changes to the second fan-out line FOL2, etc.

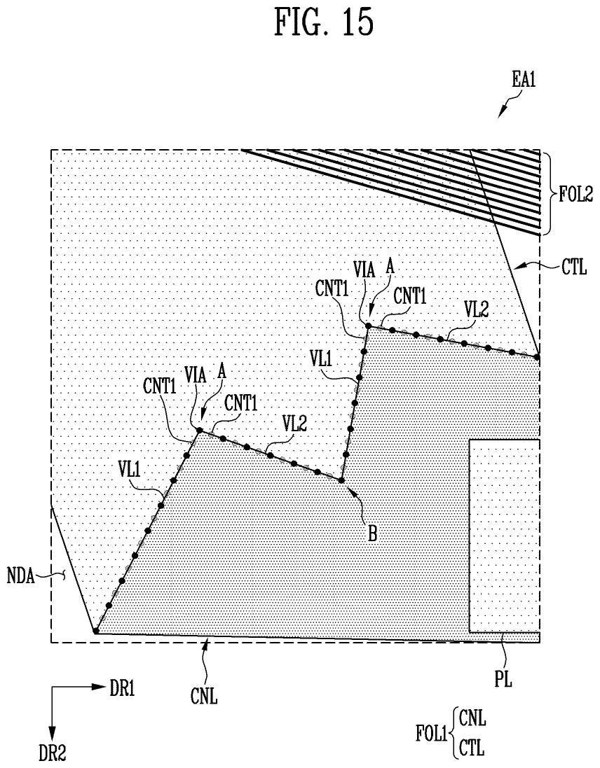

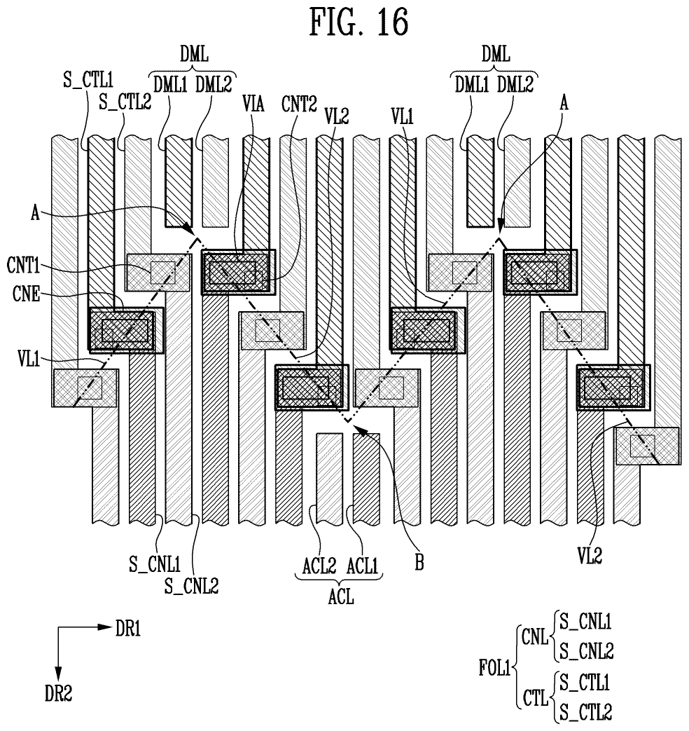

FIG. 15 is a schematic plan view showing a part of a display device in accordance with an embodiment, corresponding to the EA1 portion in FIG. 2, and FIG. 16 is a schematic diagram schematically illustrating the first fan-out line FOL1 in FIG. 15.

In the embodiments of FIG. 15 and FIG. 16, differences from the embodiment described above will be mainly described in order to avoid repetitive descriptions.

Referring to FIGS. 2, 15, and 16, some of the plurality of vias VIA and some of the plurality of first contact holes CNT1 may be arranged along two first virtual lines VL1 in a portion of the overlapping area between the intermediate wiring line CTL and the connection wiring line CNL in a plan view. Each of the two first virtual lines VL1 may extend in a first inclined direction inclined to the extension direction of the intermediate wiring line CTL and the connection wiring line CNL.

In a plan view, the rest of the plurality of vias VIA and the rest of the plurality of first contact holes CNT1 may be arranged along two second virtual lines VL2 in another portion of the overlapping area between the intermediate wiring line CTL and the connection wiring line CNL. Each of the two second virtual lines VL2 may extend along a second inclined direction, which is inclined to the extension direction of the intermediate wiring line CTL and the connection wiring line CNL and faces the first inclined direction.

In an embodiment, the plurality of vias VIA and the plurality of first contact holes CNT1, which are arranged along the two first virtual lines VL1 and the two second virtual lines VL2, may have an arrangement of two wedge shapes such as an “M” shape in a plan view, but the present disclosure is not limited thereto.

A dummy pattern DML may be disposed at the vertex A of each of the two wedge shapes as shown in FIG. 16. The dummy pattern DML may include a first dummy pattern DML1 and a second dummy pattern DML2 that are disposed spaced apart. The first dummy pattern DML1 may be disposed on the same layer as the first sub-intermediate wiring line S_CTL1, and the second dummy pattern DML2 may be disposed on the same layer as the second sub-intermediate wiring line S_CTL2. The first and second dummy patterns DML1 and DML2 may be electrically isolated from the connection wiring line CNL and the intermediate wiring line CTL.

In the two wedge shapes, an additional conductive pattern ACL may be disposed near the boundary point B between a first wedge shape and a second wedge shape adjacent thereto as shown in FIG. 16. The additional conductive pattern ACL may include a first additional conductive pattern ACL1 and a second additional conductive pattern ACL2 that are disposed spaced apart. The first additional conductive pattern ACL1 may be disposed on the same layer as the first sub-connection wiring line S_CNL1, and the second additional conductive pattern ACL2 may be disposed on the same layer as the second sub-connection wiring line S_CNL2. For example, the first additional conductive pattern ACL1 may be formed of the first conductive layer (see “C1” in FIG. 14), and the second additional conductive pattern ACL2 may be formed of the second conductive layer (see “C2” in FIG. 14). The first and second additional conductive patterns ACL1 and ACL2 may be electrically isolated from the connection wiring line CNL and the intermediate wiring line CTL. The first additional conductive pattern ACL1 and the second additional conductive pattern ACL2 may be disposed near the boundary point B between two adjacent wedge shapes in order to compensate for the density difference of the wiring line and/or pattern in an area of the non-display area NDA where the first fan-out line FOL1 is located.

According to the embodiment described above, as the vias VIA and the first contact holes CNT1 located at the connection point between the connection wiring line CNL and the intermediate wiring line CTL are arranged along the first virtual line VL1 and the second virtual line VL2 to form the arrangement of two wedge shapes, the spacing between the connection wiring line CNL and the second fan-out line FOL2, which are formed in the same process and disposed on the same layer, can be further secured. Accordingly, additional space may be further secured for design changes to the second fan-out line FOL2, etc.

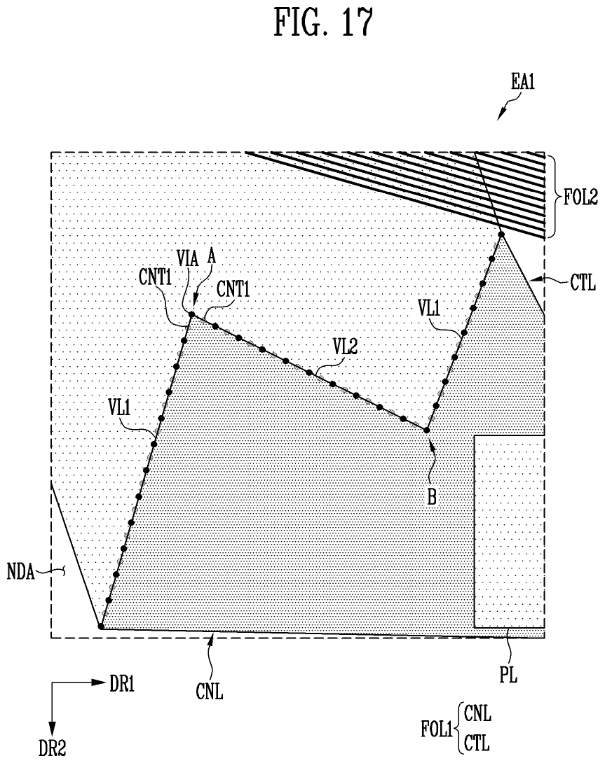

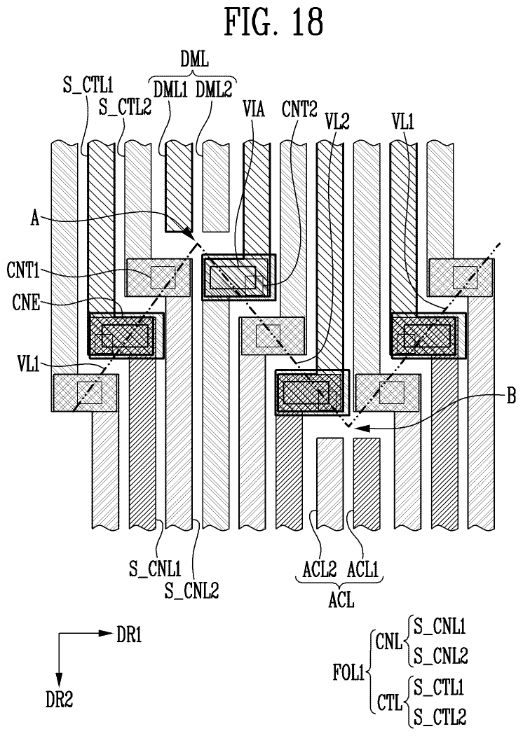

FIG. 17 is a schematic plan view showing a part of a display device in accordance with an embodiment, corresponding to the EA1 portion in FIG. 2, and FIG. 18 is a schematic diagram schematically illustrating the first fan-out line FOL1 in FIG. 17.

In the embodiment of FIG. 17 and FIG. 18, differences from the embodiment described above will be mainly described in order to avoid repetitive descriptions.

Referring to FIGS. 2, 17, and 18, some of the plurality of vias VIA and some of the plurality of first contact holes CNT1 may be arranged along two first virtual lines VL1 in a portion of the overlapping area between the intermediate wiring line CTL and the connection wiring line CNL in a plan view. Each of the two first virtual lines VL1 may extend in a first inclined direction, which is inclined to the extension direction of the intermediate wiring line CTL and the connection wiring line CNL.

In a plan view, the rest of the plurality of vias VIA and the rest of the plurality of first contact holes CNT1 may be arranged along one second virtual line VL2 in another portion of the overlapping area between the intermediate wiring line CTL and the connection wiring line CNL. The one second virtual line VL2 may extend along a second inclined direction, which is inclined to the extension direction of the intermediate wiring line CTL and the connection wiring line CNL and faces the first inclined direction.

In an embodiment, the plurality of vias VIA and the plurality of first contact holes CNT1, which are arranged along the two first virtual lines VL1 and the one second virtual line VL2, may form a wedge-shaped arrangement in an “N” shape in a plan view, but the present disclosure is not limited thereto.

A dummy pattern DML may be disposed near the vertex A of the wedge shape corresponding to the end point of one first virtual line VL1 and the start point of one second virtual line VL2, as shown in FIG. 18. The dummy pattern DML may include a first dummy pattern DML1 and a second dummy pattern DML2. The first dummy pattern DML1 may be formed in the same process as the first sub-intermediate wiring line S_CTL1 and may be disposed on the same layer as the first sub-intermediate wiring line S_CTL1. The second dummy pattern DML2 may be formed in the same process as the second sub-intermediate wiring line S_CTL2 and may be disposed on the same layer as the second sub-intermediate wiring line S_CTL2.

An additional conductive pattern ACL may be disposed near one area B corresponding to the end point of the one second virtual line VL2 and the start point of another first virtual line VL1, as shown in FIG. 18. The additional conductive pattern ACL may include a first additional conductive pattern ACL1 and a second additional conductive pattern ACL2. The first additional conductive pattern ACL1 may be formed in the same process as the first sub-connection wiring line S_CNL1 and may be disposed on the same layer as the first sub-connection wiring line S_CNL1. The second additional conductive pattern ACL2 may be formed in the same process as the second sub-connection wiring line S_CNL2 and may be disposed on the same layer as the second sub-connection wiring line S_CNL2.

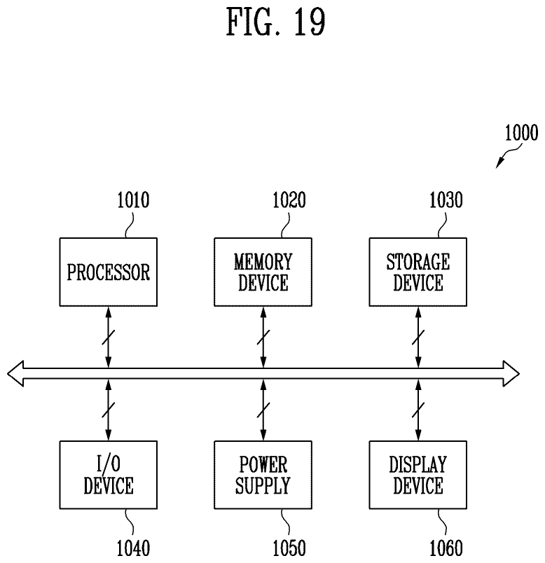

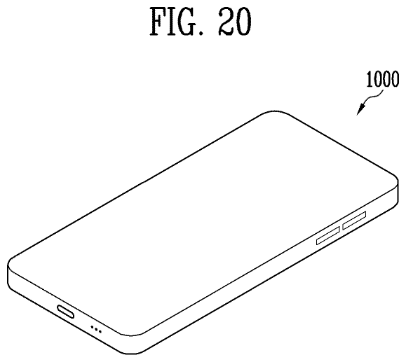

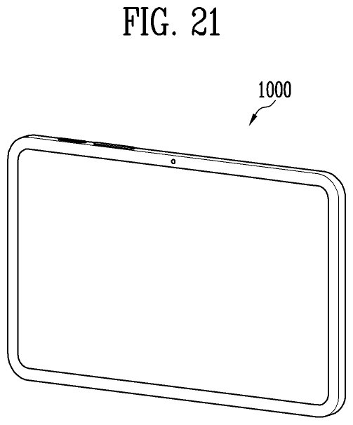

FIG. 19 is a schematic block diagram illustrating an electronic device in accordance with an embodiment. FIG. 20 is a schematic diagram illustrating an example where the electronic device of FIG. 19 is implemented as a smartphone. FIG. 21 is a schematic diagram illustrating an example where the electronic device of FIG. 19 is implemented as a tablet computer.

Referring to FIGS. 19 to 21, the electronic device 1000 may include a processor 1010, a memory device 1020, a storage device 1030, an input/output (I/O) device 1040, a power supply 1050, and a display device 1060. The display device 1060 may be the display device DD of FIGS. 1 and 2. The electronic device 1000 may further include various ports for communication with a video card, a sound card, a memory card, a USB device, or other systems. In an embodiment, as illustrated in FIG. 20, the electronic device 1000 may be implemented as a smartphone. In an embodiment, as illustrated in FIG. 21, the electronic device 1000 may be implemented as a tablet computer. However, the aforementioned examples are illustrative, and the electronic device 1000 is not necessarily limited to the aforementioned examples. For example, the electronic device 1000 may be implemented as a cellular phone, a video phone, a smartpad, a smartwatch, a navigation device for vehicles, a computer monitor, a laptop computer, a head-mounted display device, or the like.

The processor 1010 may perform specific calculations or tasks. In an embodiment, the processor 1010 may be a micro processor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus.

The memory device 1020 may store data needed to perform the operation of the electronic device 1000. For example, the memory device 1020 may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, and so on.

The storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be included in the I/O device 1040.

The power supply 1050 may supply power needed to perform the operation of the electronic device 1000. For example, the power supply 1050 may be a power management integrated circuit (PMIC).

The display device 1060 may display an image corresponding to visual information of the electronic device 1000. Here, the display device 1060 may be an organic light emitting diode (OLED) display device or a quantum dot light emitting display device, but is not necessarily limited thereto. The display device 1060 may be connected to other components through the buses or other communication links.

Although the descriptions have been made with reference to an embodiment of the present disclosure, those skilled in the art or those having ordinary knowledge in the art will understand that the present disclosure can be modified and changed in various ways within a scope that does not depart from the technical field of the present disclosure set forth in the claims to be described below.

Therefore, the scope of the present disclosure should not be limited to the contents described in the detailed description of the specification, but should be defined by the claims.

What is claimed is:

1. A display device comprising:
a substrate having a display area and a non-display area surrounding the display area; and
a first fan-out line disposed in the non-display area,
wherein the first fan-out line comprises a connection wiring line and an intermediate wiring line that are electrically connected to each other,
the connection wiring line and the intermediate wiring line are disposed on different layers,
the connection wiring line comprises a first sub-connection wiring line and a second sub-connection wiring line that are disposed spaced apart,
the intermediate wiring line comprises a first sub-intermediate wiring line and a second sub-intermediate wiring line that are disposed spaced apart,
an end of the first sub-connection wiring line and an end of the first sub-intermediate wiring line are electrically connected through a via,
an end of the second sub-connection wiring line and an end of the second sub-intermediate wiring line are electrically connected through a first contact hole,
the via comprises a plurality of vias, and the first contact hole comprises a plurality of first contact holes, and
the plurality of vias and the plurality of first contact holes are arranged along a direction inclined to an extension direction of the connection wiring line and the intermediate wiring line.

2. The display device of claim 1, wherein the plurality of vias and the plurality of first contact holes are arranged alternately along the inclined direction.

3. The display device of claim 1, wherein the first sub-connection wiring line is formed of a first conductive layer,
the second sub-connection wiring line is formed of a second conductive layer which is disposed on the first conductive layer with a gate insulating layer interposed therebetween,
the second sub-intermediate wiring line is formed of a third conductive layer which is disposed on the second conductive layer with an interlayer insulating layer interposed therebetween, and
the first sub-intermediate wiring line is formed of a fourth conductive layer which is disposed on the third conductive layer with a via layer interposed therebetween, and
wherein the interlayer insulating layer is disposed on the gate insulating layer, and the via layer is disposed on the interlayer insulating layer.

4. The display device of claim 3, wherein one second sub-connection wiring line is disposed between two adjacent first sub-connection wiring lines, and
one second sub-intermediate wiring line is disposed between two adjacent first sub-intermediate wiring lines.

5. The display device of claim 3, wherein the end of the first sub-connection wiring line comprises a first protrusion protruding in a first direction which intersects an extension direction of the first sub-connection wiring line,
the end of the second sub-connection wiring line comprises a second protrusion protruding in the first direction which intersects an extension direction of the second sub-connection wiring line,
the end of the first sub-intermediate wiring line comprises a third protrusion protruding in a second direction which intersects an extension direction of the first sub-intermediate wiring line,
the end of the second sub-intermediate wiring line comprises a fourth protrusion protruding in the second direction which intersects an extension direction of the second sub-intermediate wiring line, and
the first protrusion and the third protrusion overlap each other, and the second protrusion and the fourth protrusion overlap each other.

6. The display device of claim 5, further comprises a contact electrode formed of the third conductive layer and located between the first protrusion and the third protrusion,
wherein the via layer comprises the via extending to a part of the contact electrode,
the interlayer insulating layer comprises the first contact hole extending to a part of the second protrusion and a second contact hole extending to a part of the first protrusion,
the third protrusion is electrically connected to the contact electrode through the via, and
the contact electrode is electrically connected to the first protrusion through the second contact hole.

7. The display device of claim 6, wherein the via is located in a first overlap area where the first protrusion and the third protrusion overlap in a plan view,
the first contact hole is located in a second overlap area where the second protrusion and the fourth protrusion overlap in a plan view, and
a longitudinal direction of the via is parallel to a protrusion direction of the first and third protrusions.

8. The display device of claim 7, wherein the fourth protrusion is electrically connected to the second protrusion through the first contact hole.

9. The display device of claim 7, wherein some of the plurality of vias and some of the plurality of first contact holes are arranged along a first virtual line extending in a first inclined direction which is inclined to the extension direction of the intermediate wiring line and the connection wiring line in a plan view,
the rest of the plurality of vias and the rest of the plurality of first contact holes are arranged along a second virtual line extending in a second inclined direction which is a different direction than the first inclined direction and faces the first inclined direction in a plan view, and
the first virtual line and the second virtual line form a wedge shape.

10. The display device of claim 9, wherein each of the first to fourth protrusions comprises a first sub-protrusion arranged along the first inclined direction and a second sub-protrusion arranged along the second inclined direction, and
the first sub-protrusion and the second sub-protrusion protrude in opposite directions to each other.

11. The display device of claim 9, further comprises a dummy pattern located at a vertex of the wedge shape in the non-display area.

12. The display device of claim 11, wherein the dummy pattern comprises a first dummy pattern and a second dummy pattern that are disposed spaced apart,
the first dummy pattern is formed of the fourth conductive layer, and the second dummy pattern is formed of the third conductive layer, and
the first and second dummy patterns are electrically isolated from the connection wiring line and the intermediate wiring line.

13. The display device of claim 9, further comprises:
sub-pixels disposed in the display area; and
a second fan-out line disposed in the non-display area, electrically connected to the sub-pixels, and electrically isolated from the first fan-out line,
wherein the second fan-out line does not overlap the connection wiring line but overlaps the intermediate wiring line.

14. The display device of claim 13, wherein the second fan-out line is disposed spaced apart from the plurality of vias and the plurality of first contact holes in a plan view.

15. The display device of claim 13, wherein the sub-pixels comprise:
a pixel circuit layer disposed on the substrate and comprising at least one transistor; and
a light-emitting element disposed on the pixel circuit layer and electrically connected to the transistor.

16. A display device comprising:
sub-pixels disposed in a display area of a substrate;
a first fan-out line disposed in a non-display area of the substrate; and
a second fan-out line disposed in the non-display area and electrically isolated from the first fan-out line,
wherein the first fan-out line comprises a connection wiring line and an intermediate wiring line electrically connected to the connection wiring line,
the connection wiring line comprises a first sub-connection wiring line formed of a first conductive layer and a second sub-connection wiring line formed of a second conductive layer on the first conductive layer,
the intermediate wiring line comprises a second sub-intermediate wiring line formed of a third conductive layer on the second conductive layer and a first sub-intermediate wiring line formed of a fourth conductive layer on the third conductive layer,
the first sub-connection wiring line and the first sub-intermediate wiring line are electrically connected through a via,
the second sub-connection wiring line and the second sub-intermediate wiring line are electrically connected through a first contact hole,
the via comprises a plurality of vias, and the first contact hole comprises a plurality of first contact holes,
some of the plurality of vias and some of the first contact holes are arranged along a first virtual line extending in a first inclined direction which intersects an extension direction of the intermediate wiring line and the connection wiring line,
the rest of the plurality of vias and the rest of the first contact holes are arranged along a second virtual line extending in a second inclined direction which is a different direction than the first inclined direction and faces the first inclined direction, and
the first virtual line and the second virtual line form a wedge shape.

17. The display device of claim 16, wherein an end of the first sub-connection wiring line and an end of the first sub-intermediate wiring line overlap a corresponding via among the plurality of vias,
an end of the second sub-connection wiring line and an end of the second sub-intermediate wiring line overlap a corresponding first contact hole among the plurality of first contact holes,
the end of the first sub-connection wiring line protrudes in a first direction which intersects an extension direction of the first sub-connection wiring line,
the end of the second sub-connection wiring line protrudes in the first direction which intersects an extension direction of the second sub-connection wiring line,
the end of the first sub-intermediate wiring line protrudes in a second direction which intersects an extension direction of the first sub-intermediate wiring line, and
the end of the second sub-intermediate wiring line protrudes in the second direction which intersects an extension direction of the second sub-intermediate wiring line.

18. The display device of claim 17, further comprises a contact electrode located between the end of the first sub-connection wiring line and the end of the first sub-intermediate wiring line and formed of the third conductive layer,
wherein the contact electrode is disposed on the same layer as the second sub-intermediate wiring line.

19. The display device of claim 17, further comprises a dummy pattern located at a vertex of the wedge shape in the non-display area,
wherein the dummy pattern is electrically isolated from the connection wiring line and the intermediate wiring line.

20. The display device of claim 17, wherein the first sub-connection wiring line and the second sub-connection wiring line are disposed spaced apart from each other in a plan view, and
the first sub-intermediate wiring line and the second sub-intermediate wiring line are disposed spaced apart from each other in a plan view.

21. An electronic device, comprising:
a processor configured to provide input image data to a display device; and
the display device configured to display an image based on the input image data,
wherein the display device comprises:
a substrate having a display area and a non-display area surrounding the display area; and
a first fan-out line disposed in the non-display area,
wherein the first fan-out line comprises a connection wiring line and an intermediate wiring line that are electrically connected to each other,
the connection wiring line and the intermediate wiring line are disposed on different layers,
the connection wiring line comprises a first sub-connection wiring line and a second sub-connection wiring line that are disposed spaced apart,
the intermediate wiring line comprises a first sub-intermediate wiring line and a second sub-intermediate wiring line that are disposed spaced apart,
an end of the first sub-connection wiring line and an end of the first sub-intermediate wiring line are electrically connected through a via,
an end of the second sub-connection wiring line and an end of the second sub-intermediate wiring line are electrically connected through a first contact hole,
the via comprises a plurality of vias, and the first contact hole comprises a plurality of first contact holes, and
the plurality of vias and the plurality of first contact holes are arranged along a direction inclined to an extension direction of the connection wiring line and the intermediate wiring line.
